(19) United States
(12) Patent Application Publication
(10) Pub. No.: US 2026/0033085 A1
(43) Pub. Date: Jan. 29, 2026

(54) DISPLAY APPARATUS

(71) Applicant: LG Display Co., Ltd., Seoul (KR)

(72) Inventors: HyeSun Jung, Seoul (KR); TaeYoon Kim, Seoul (KR); BungGoo Kim, Paju-si (KR); HyoungHo Ahn, Paju-si (KR); HeeWon Lee, Paju-si (KR); JunYoung Jo, Paju-si (KR)

(73) Assignee: LG Display Co., Ltd., Seoul (KR)

(21) Appl. No.: 19/253,626

(22) Filed: Jun. 27, 2025

(30) Foreign Application Priority Data
Jul. 25, 2024 (KR) 10-2024-0098890

(51) Int. Cl. H10H 29/49; H01L 25/16; H10H 29/37

(52) U.S. Cl. CPC H10H 29/49; H01L 25/167; H10H 29/37

(57) ABSTRACT

A display apparatus includes a substrate which has an active area, a first non-active area, a bending area, and a second non-active area; and a plurality of connection lines which are at least partially disposed in the second non-active area and include a first connection line; a second connection line which is disposed on the first connection line and has one end and the other end respectively disposed at the outside more than one end and the other end of the first connection line; a third connection line which is disposed on the second connection line and has one end disposed at the outside more than the other end of the first connection line; and a fourth connection line which is disposed on the third connection line and has one end disposed at the outside more than the other end of the second connection line.

### CROSS-REFERENCE TO RELATED APPLICATION

This application claims the priority of Korean Patent Application No. 10-2024-0098890, filed on Jul. 25, 2024, in the Korean Intellectual Property Office, the disclosure of which is incorporated herein by reference.

### BACKGROUND

### Field

The present disclosure relates to a display apparatus.

### Description of the Related Art

Display apparatuses are being applied to various electronic devices, such as TVs, mobile phones, notebooks, and tablets.

As display apparatuses, there are an organic light emitting display (OLED) which is a self-emitting device and a liquid crystal display (LCD) which requires a separate light source.

Recently, a display apparatus including a light emitting diode (LED) is attracting attention as a next generation display apparatus. The light emitting diode is formed of an inorganic material, rather than an organic material so that lighting speed is faster, a luminous efficiency is excellent, and an image with a higher luminance may be displayed, as compared with the liquid crystal display or the organic light emitting display.

### SUMMARY

An object to be achieved by the present disclosure is to provide a display apparatus in which clumping of conductive balls is improved.

An object to be achieved by the present disclosure is to provide a display apparatus in which a short-circuit defect between pad electrodes caused by the clumping of conductive balls is minimized or suppressed.

An object to be achieved by the present disclosure is to provide a display apparatus in which a burnt defect of a conductive ball caused by the clumping of conductive balls is minimized or suppressed.

An object to be achieved by the present disclosure is to provide a display apparatus which suppresses a potential defect due to the clumping of conductive balls to be driven with a low power in terms of reduction of a power consumption.

Objects of the present disclosure are not limited to the above-mentioned objects, and other objects, which are not mentioned above, can be clearly understood by those skilled in the art from the following descriptions.

According to an aspect of the present disclosure, a display apparatus includes: a substrate having an active area, a first non-active area enclosing the active area, a bending area extending from the first non-active area and being bendable, and a second non-active area extending from the bending area; a pixel driving circuit disposed on the substrate in the active area; a protection layer which is disposed so as to enclose the pixel driving circuit; a plurality of banks disposed on the protection layer in the active area; a plurality of micro LEDs which is disposed on the plurality of banks in the active area and is connected to the pixel driving circuit; a plurality of connection lines, at least partially disposed on the protection layer in the second non-active area; and a plurality of pad electrodes which is disposed on the plurality of connection lines in the second non-active area. The plurality of connection lines includes: a first connection line; a second connection line which is disposed on the first connection line and has one end and the other end respectively disposed at the outside more than one end and the other end of the first connection line, and is connected to the first connection line through a first contact hole; a third connection line which is disposed on the second connection line and has one end disposed at the outside more than the other end of the first connection line, and is connected to the second connection line through a second contact hole; and a fourth connection line which is disposed on the third connection line and has one end disposed at the outside more than the other end of the second connection line, and is connected to the third connection line through a third contact hole. Accordingly, clumping of conductive balls disposed between the flexible circuit board and the plurality of pad electrodes may be minimized or suppressed.

According to another aspect of the present disclosure, a display apparatus includes: a substrate having an active area, a first non-active area enclosing the active area, a bending area extending from the first non-active area and being bendable, and a second non-active area which extends from the bending area and has a plurality of pad electrodes and a flexible circuit board connected to the plurality of pad electrodes disposed therein; a pixel driving circuit disposed on the substrate in the active area; a first protection layer and a second protection layer on the first protection layer which are disposed so as to enclose a side surface of the pixel driving circuit; a plurality of micro LEDs which is disposed on the second protection layer in the active area and is connected to the pixel driving circuit; and a plurality of connection lines, at least partially disposed between the second protection layer and the plurality of pad electrodes in the second non-active area, wherein the plurality of connection lines includes: a first connection line; a second connection line which is disposed so as not to at least partially overlap the first connection line and to be connected to the first connection line, on the first connection line; a third connection line which is disposed so as not to at least partially overlap the second connection line and to be connected to the second connection line, on the second connection line; and a fourth connection line which is disposed so as not to at least partially overlap the third connection line and to be connected to the third connection line, on the third connection line.

According to another aspect of the present disclosure, a display apparatus includes: a substrate having an active area and a non-active area; a plurality of micro LEDs disposed in the active area; a plurality of pad electrodes disposed in the non-active area and connected to a flexible circuit board; and a plurality of connection lines each disposed in different layer, at least partially disposed in the non-active area, wherein some of the plurality of connection lines overlap with each other, and wherein there are no more than two connection lines in an overlapping direction.

Other detailed matters of example embodiments are included in the detailed description and drawings.

According to an aspect of the present disclosure, an overlapping area between second connection lines which are disposed below the plurality of pad electrodes is minimized or reduced to ensure a flatness of an area in which a plurality of pad electrodes is disposed.

According to an aspect of the present disclosure, a flatness of an area in which the plurality of pad electrodes is disposed is ensured or provided to minimize or suppress the clumping of conductive balls disposed between the flexible circuit board and the plurality of pad electrodes.

According to an aspect of the present disclosure, the short-circuit defect between the plurality of pad electrodes caused by the clumping of conductive balls can be minimized or suppressed.

According to an aspect of the present disclosure, the burnt defect of conductive balls caused by the clumping of conductive balls can be minimized or suppressed.

According to an aspect of the present disclosure, a potential defect due to the clumping of conductive balls is minimized or suppressed, and the lifespan of the display apparatus is improved to be driven at a low power in terms of reduction of a power consumption.

The effects according to the present disclosure are not limited to the contents exemplified above, and various additional effects are included in the present specification.

Additional features and aspects of the present disclosure are set forth in the description that follows and in part will become apparent from the description or may be learned by practice of the inventive concepts provided herein. Other features and aspects of the inventive concepts may be realized and attained by the structure particularly pointed out in, or derivable from, the written description, claims hereof, and the appended drawings.

It is to be understood that both the foregoing general description and the following detailed description of the present disclosure are by way of example and are intended to provide further explanation of the disclosures as claimed.

### BRIEF DESCRIPTION OF DRAWINGS

The accompanying drawings, which are included to provide a further understanding of the present disclosure and are incorporated in and constitute a part of this application, illustrate various aspects of the present disclosure and together with the description serve to explain various principles of the present disclosure. In the drawings:

FIG. 1 is an exploded perspective view of a display apparatus according to an example embodiment of the present disclosure;

FIG. 2 is a plan view of a display apparatus according to an example embodiment of the present disclosure;

FIG. 3 is an enlarged view of a display apparatus according to an example embodiment of the present disclosure;

FIG. 4 is a view illustrating a circuit structure according to an example embodiment of the present disclosure;

FIG. 5 is a plan view of a display apparatus according to an example embodiment of the present disclosure;

FIG. 6 is a plan view of a display apparatus according to an example embodiment of the present disclosure;

FIG. 7 is a plan view of a display apparatus according to an example embodiment of the present disclosure;

FIG. 8 is a cross-sectional view taken along VIII-VIII′ in FIG. 3;

FIG. 9 is a cross-sectional view of a display apparatus according to an example embodiment of the present disclosure;

FIG. 10 is a cross-sectional view of a display apparatus according to another example embodiment of the present disclosure;

FIG. 11 is a cross-sectional view of a display apparatus according to still another example embodiment of the present disclosure;

FIG. 12 is a cross-sectional view of a display apparatus according to still another example embodiment of the present disclosure; and

FIGS. 13 to 16 are views illustrating devices to which a display apparatus according to example embodiments of the present disclosure can be applied.

### DETAILED DESCRIPTION

Advantages and characteristics of the present disclosure and a method of achieving the advantages and characteristics will be clear by referring to example embodiments described below in detail together with the accompanying drawings. However, the present disclosure is not limited to the example embodiments disclosed herein but can be implemented in various other forms. The below example embodiments are provided by way of example only so that those skilled in the art can fully understand the disclosures of the present disclosure and the scope of the present disclosure.

The shapes, sizes, ratios, angles, numbers, and the like illustrated in the accompanying drawings for describing the example embodiments of the present disclosure are merely examples, and the present disclosure is not limited thereto. Like reference numerals generally denote like elements throughout the specification. Further, in the following description of the present disclosure, a detailed explanation of known related technologies may be omitted to avoid unnecessarily obscuring the subject matter of the present disclosure. The terms such as “including,” “having,” and “consist of” used herein are generally intended to allow other components to be added unless the terms are used with a more limiting term like “only”. Any references to singular may include plural, and vice versa, unless expressly stated otherwise.

Components are interpreted to include an ordinary error range even if not expressly stated.

Where the position relation between two parts is described using the terms such as “on”, “above”, “below”, and “next”, one or more parts may be positioned between the two parts unless the terms are used with a more limiting term like “immediately” or “directly”.

Where temporal relationships are explained, terms such as “after,” “following,” “subsequent to,” or “before,” etc., may include non-consecutive cases unless a more limiting term like “immediately” or “directly” is used.

Terms such as “first,” “second,” etc., are used to describe various components, but these components are not limited by these terms. These terms are merely used to refer to one component separately from another. Therefore, a first component mentioned herein could be a second component, and vice versa, within the technical scope of the present disclosure.

In describing the components of the present disclosure, terms such as first, second, A, B, (a), or (b) may be used. These terms are only intended to refer to that one component separately from other components, and the nature, order, sequence, or number of the respective component is not limited by these terms.

Where a component is described as being “connected,” “coupled,” “joined,” or “attached” to another component, it should be understood that the component may be directly connected, coupled, joined, or attached to the another component, but unless explicitly specified otherwise, it may also be indirectly connected, coupled, joined, or attached to the another component with other component intervened therebetween.

Where a component or layer is described as being “in contact with” or “overlapping” another component or layer, the component or layer may directly contact or overlap the another component or layer, but unless explicitly specified otherwise, it should be understood that it may also indirectly contact or overlap with the another component with other component intervened therebetween.

The term “at least one” should be understood to include all combinations of one or more of the associated components. For example, “at least one of first, second, and third components” means not only the first, second, or third component, but also includes all combinations of two or more components from among the first, second, and third components.

The terms “first direction”, “second direction”, “third direction”, “X-axis direction”, “Y-axis direction”, and “Z-axis direction” should not be interpreted solely as geometric relationships perpendicular to each other, but may indicate broader directionality within the range where the configuration of the present disclosure can function.

The features of various embodiments in the present disclosure may be partially or wholly combined or associated with each other, various technical interlocking and operations are possible, and each embodiment may be implemented independently of each other or may be implemented together in an associated relationship.

Hereinafter, a display apparatus according to example embodiments of the present disclosure will be described in detail with reference to accompanying drawings.

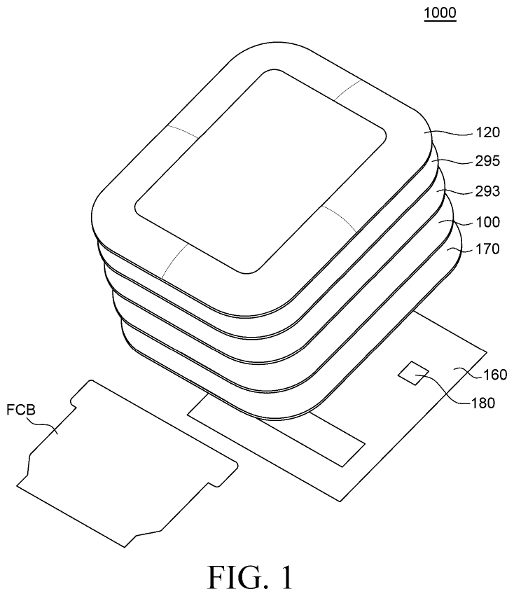

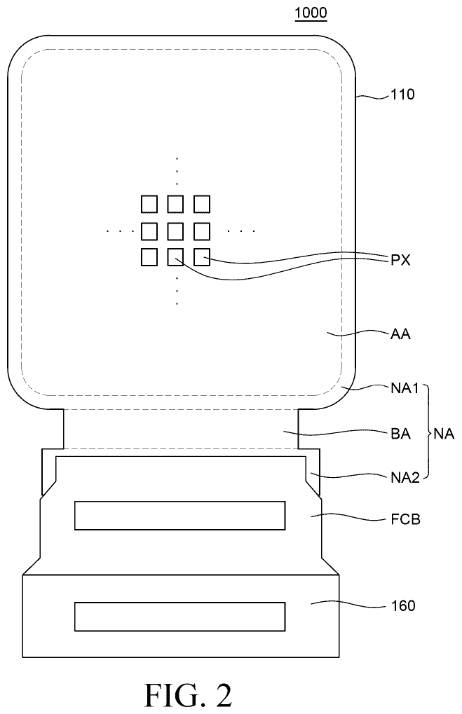

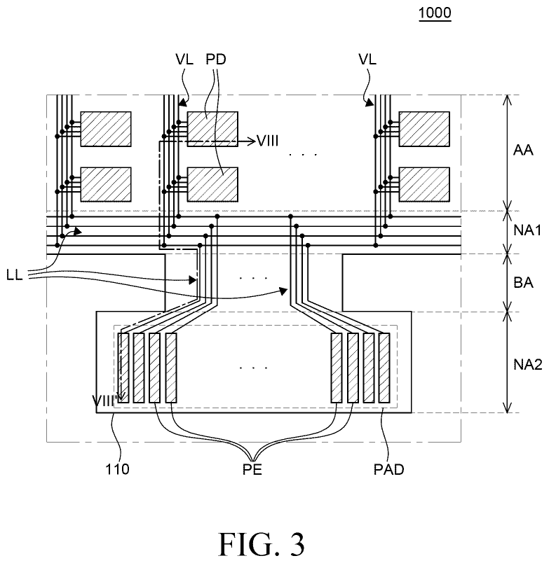

FIG. 1 is an exploded perspective view illustrating a display apparatus according to an example embodiment of the present disclosure. FIG. 2 is a plan view of a display apparatus according to an example embodiment of the present disclosure. FIG. 3 is an enlarged view of a display apparatus according to an example embodiment of the present disclosure.

As shown in FIGS. 1 to 3, a display apparatus 1000 according to an example embodiment of the present disclosure may include a display panel 100, a polarization layer 293, an adhesive layer 295, a cover member 120, a support substrate 170, a flexible circuit board FCB, and a printed circuit board 160.

For example, the display panel 100 of the display apparatus 1000 may include a substrate 110. The substrate 110 may be a member which supports other components of the display apparatus 1000. The substrate 110 may be formed of an insulating material. For example, the substrate 110 may be formed of glass or resin. Further, the substrate 110 may also be formed of a material having flexibility. For example, the substrate 110 may be formed of a plastic material having flexibility, such as polyimide (PI). However, the example embodiments of the present disclosure are not limited thereto.

The display panel 100 may implement information, videos, and/or images which are provided to users. For example, the display panel 100 may include an active area AA and a non-active area NA. For example, the substrate 110 may include an active area AA and a non-active area NA. The active area AA and the non-active area NA are not mentioned to be limited to the substrate 110, but may be mentioned for the entire display apparatus 1000.

The active area AA may be an area where images are displayed. The active area AA may include a plurality of pixels PX. Each of the plurality of pixels PX may be configured by a plurality of sub pixels. A plurality of micro LEDs may be disposed in each of the plurality of sub pixels.

The non-active area NA may be an area where no image is displayed. In the non-active area NA, various wiring lines and circuits for driving the plurality of pixels PX of the active area AA may be disposed. For example, in the non-active area NA, various wiring lines and driving circuits may be mounted and a pad unit PAD to which an integrated circuit and a printed circuit are connected may be disposed, but the example embodiments of the present disclosure are not limited thereto.

For example, the driving circuit may be a data driving circuit and/or a gate driving circuit, but the example embodiments of the present disclosure are not limited thereto. Wiring lines through which a control signal for controlling driving circuits is supplied may be disposed. For example, the control signal may include various timing signals including a clock signal, an input data enable signal, and synchronization signals, but the example embodiments of the present disclosure are not limited thereto. The control signal may be received through the pad unit PAD. For example, in the non-active area NA, link lines LL may be disposed to transmit signals. For example, driving components, such as the flexible circuit board FCB and the printed circuit board 160, may be connected to the pad unit PAD.

According to the present disclosure, the non-active area NA may include a first non-active area NA1, a bending area BA, and a second non-active area NA2. For example, the first non-active area NA1 may be an area which encloses at least a part of the active area AA. The bending area BA is an area extending from at least one side, among a plurality of sides of the first non-active area NA1 and may be a bendable area. The second non-active area NA2 is an area extending from the bending area BA and the pad unit PAD may be disposed therein. For example, the bending area BA may be in a bent state and the other areas of the substrate 110 excluding the bending area BA may be in a flat state. In this case, as the bending area BA is bent, the second non-active area NA2 may be located on a rear surface of the active area AA, but the example embodiments of the present disclosure are not limited thereto.

The active area AA of the substrate 110 or the display apparatus 1000 may be configured with various shapes depending on a design of the display apparatus 1000. For example, the active area AA may be configured with a rectangular shape formed with four rounded corners, but the example embodiments of the present disclosure are not limited thereto. As another example, the active area AA may be configured with a rectangular shape formed with four right-angled corners or a circular shape, but the example embodiments of the present disclosure are not limited thereto.

According to the present disclosure, a width of the second non-active area NA2 in which the plurality of pad electrodes PE is disposed may be larger than a width of the bending area BA in which only a plurality of link lines LL is disposed. Further, a width of the active area AA in which the plurality of sub pixels is disposed may be larger than a width of the bending area BA in which only a plurality of link lines LL is disposed. Even though in the drawing, it is illustrated that the width of the bending area BA is smaller than a width of the other area of the substrate 110, the shape of the substrate 110 including the bending area BA is illustrative and the example embodiments of the present disclosure are not limited thereto.

As shown in FIG. 3, a plurality of pixel driving circuits PD may be disposed in the active area AA. The plurality of pixel driving circuits PD may be circuits for driving micro LEDs of the plurality of sub pixels. Each of the plurality of pixel driving circuits PD includes a plurality of transistors including a driving transistor and a storage capacitor and supplies a control signal, a power, and a driving current to the micro LEDs of the plurality of sub pixels to control an emission operation of the plurality of micro LEDs. For example, the pixel driving circuit PD may include a power line and a signal line for controlling emission on/off of the micro LED and/or an emission time. For example, the plurality of pixel driving circuits PD may be drivers manufactured using a metal-oxide-silicon field effect transistor (MOSFET) manufacturing process on a semiconductor substrate, but the example embodiments of the present disclosure are not limited thereto. The driver includes a plurality of pixel driving circuits PD and may drive a plurality of sub pixels.

As shown in FIG. 1 together, the flexible circuit board FCB and the printed circuit board 160 may be disposed below the display panel 100. The flexible circuit board FCB and the printed circuit board 160 may be disposed at least at one edge of the display panel 100, but the example embodiments of the present disclosure are not limited thereto. One side of the flexible circuit board FCB is attached to the display panel 100 and the other side may be attached to the printed circuit board 160, but the example embodiments of the present disclosure are not limited thereto. The flexible circuit board FCB may be a flexible film, but the example embodiments of the present disclosure are not limited thereto.

A pad unit PAD including a plurality of pad electrodes PE may be disposed in the second non-active area NA2. In the pad unit PAD, a driving component including one or more flexible circuit board (or a flexible film) FCB and the printed circuit board 160 may be attached or bonded. The plurality of pad electrodes PE of the pad unit PAD is electrically connected to one or more flexible circuit boards (or flexible films) FCB and may transmit various signals (or powers) from the printed circuit board 160 and the flexible circuit board (or a flexible film) FCB to the plurality of pixel driving circuits PD of the active area AA.

The flexible circuit board (or flexible film) FCB may be a film on which various components are disposed on a base film having ductility. For example, driving ICs such as a gate driver IC or a data driver IC may be disposed in the flexible circuit board (or flexible film) FCB, but the example embodiments of the present disclosure are not limited thereto. The driving IC may be a component which processes data and driving signals to display images. The driving IC may be disposed by a chip on glass (COG), a chip on film (COF), or a tape carrier package (TCP) technique depending on a mounting method, but the example embodiments of the present disclosure are not limited thereto. The flexible circuit board (or flexible film) FCB may be attached or bonded onto the plurality of pad electrodes PE through a conductive adhesive layer, but the example embodiments of the present disclosure are not limited thereto.

The printed circuit board 160 may be a component which is electrically connected to one or more flexible circuit boards (or flexible films) FCB and supplies a signal to the driving IC. The printed circuit board 160 is disposed at one side of the flexible circuit board (or flexible film) FCB to be electrically connected to the flexible circuit board (or flexible film) FCB. On the printed circuit board 160, various components for supplying various signals to the driving IC may be disposed. For example, on the printed circuit board 160, various components, such as a timing controller, a power source, a memory, or a processor, may be disposed. For example, the printed circuit board 160 may include a power management integrated circuit (PMIC), but the example embodiments of the present disclosure are not limited thereto.

The printed circuit board 160 may include at least one hole 180, but the example embodiments of the present disclosure are not limited thereto. An internal component which senses ambient light or temperature to be supplied to a plurality of sensors may be disposed in an area corresponding to at least one hole 180. For example, the internal component may include an ambient light sensor (ALS) or a temperature sensor, but the example embodiments of the present disclosure are not limited thereto. For example, the hole 180 may be a transmission hole, but the example embodiments of the present disclosure are not limited thereto.

As shown in FIG. 1, a polarization layer 293 may be disposed on the display panel 100. The polarization layer 293 may suppress or reduce the influence on the micro LED caused by light generated from an external light source and entering the display panel 100.

A cover member 120 may be disposed on the polarization layer 293. The cover member 120 may be a member for protecting the display panel 100. The adhesive layer 295 may be disposed between the polarization layer 293 and the cover member 120. The cover member 120 may be attached to the display panel 100 using the adhesive layer 295. The adhesive layer 295 may include an optically clear adhesive (OCA), an optically clear resin (OCR), or a pressure sensitive adhesive (PSA), but the example embodiments of the present disclosure are not limited thereto.

The support substrate 170 may be disposed between the display panel 100 and the printed circuit board 160. The support substrate 170 may reinforce a rigidity of the display panel 100. The support substrate 170 may be a back plate, but the example embodiments of the present disclosure are not limited thereto.

As shown in FIGS. 1 to 3, the plurality of link lines LL may be disposed in the non-active area NA. The plurality of link lines LL may be wiring lines which transmit various signals from one or more flexible circuit boards (or flexible films) FCB and the printed circuit board 160 to the active area AA. The plurality of link lines LL extends from the plurality of pad electrodes PE of the second non-active area NA2 toward the bending area BA and the first non-active area NA1 to be electrically connected to the plurality of driving lines VL of the active area AA. The plurality of pixel driving circuits PD is supplied with signals from one or more flexible circuit board (or flexible films) FCB and the printed circuit board 160 through the driving line VL of the active area AA and the link line LL of the non-active area NA to be driven.

For example, the plurality of driving lines VL may be wiring lines for transmitting a signal output from the flexible circuit board (or flexible film) FCB and the printed circuit board 160 to the plurality of pixel driving circuits PD together with the plurality of link lines LL. The plurality of driving lines VL is disposed in the active area AA to be electrically connected to each of the plurality of pixel driving circuits PD. The plurality of driving lines VL extends toward the non-active area NA from the active area AA to be electrically connected to the plurality of link lines LL. Accordingly, a signal output from the flexible circuit board (or flexible film) FCB and the printed circuit board 160 may be transmitted to each of the plurality of pixel driving circuits PD through the plurality of link lines LL and the plurality of driving lines VL.

As the bending area BA is bent, a part of the plurality of link lines LL may be bent together. A stress is concentrated in the bent part of the link line LL, which may cause a crack on the link line LL. Accordingly, the plurality of link lines LL may be configured by a conductive material having excellent ductility to reduce the crack caused when the bending area BA is bent. For example, the plurality of link lines LL may be configured by a conductive material having excellent ductility, such as gold (Au), silver (Ag), or aluminum (Al), but the example embodiments of the present disclosure are not limited thereto. Further, the plurality of link lines LL may be configured by one of various conductive materials used for the active area AA. For example, the plurality of link lines LL may be configured by molybdenum (Mo), chrome (Cr), titanium (Ti), nickel (Ni), neodymium (Nd), copper (Cu), and an alloy of silver (Ag) and magnesium (Mg) or an alloy thereof, but the example embodiments of the present disclosure are not limited thereto. The plurality of link lines LL may be configured by a multi-layered structure including various conductive materials. For example, the plurality of link lines LL may be configured with a triple layered structure of titanium (Ti)/aluminum (Al)/titanium (Ti), but the example embodiments of the present disclosure are not limited thereto.

The plurality of link lines LL may be configured with various shapes to reduce a stress. At least a part of the plurality of link lines LL disposed on the bending area BA may extend in the same direction as an extending direction of the bending area BA or extend in a different direction from the extending direction of the bending area BA to reduce a stress. For example, when the bending area BA extends in one direction toward the second non-active area NA2 from the first non-active area NA1, at least a part of the link line LL disposed on the bending area BA may extend in an inclined direction from one direction. As another example, at least a part of the plurality of link lines LL may be configured by various shapes of patterns. For example, at least a part of the plurality of link lines LL disposed on the bending area BA may have a shape in which a conductive pattern having at least one shape of a diamond shape, a rhombus shape, a trapezoidal wave shape, a triangular wave shape, a sawtooth wave shape, a sine wave shape, a circular shape, an omega ((2) shape may be repeatedly disposed. However, the example embodiments of the present disclosure are not limited thereto. Accordingly, to minimize or reduce a stress concentrated on the plurality of link lines LL and a crack caused thereby, a shape of the plurality of link lines LL may be various shapes including the above-mentioned shapes, but the example embodiments of the present disclosure are not limited thereto.

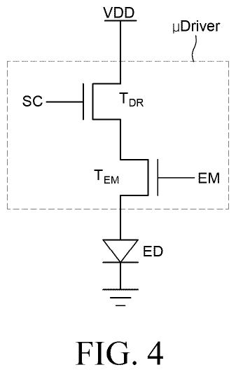

FIG. 4 is a view illustrating a circuit structure according to an example embodiment of the present disclosure.

A pixel driving circuit PD may include a micro driver μDriver. The micro LED ED is electrically connected to the micro driver μDriver of the pixel driving circuit PD to be driven. Even though in FIG. 4, it is illustrated that one micro LED ED is connected to one micro driver μDriver, but the present disclosure is not limited thereto. For example, eight micro LEDs (ED) may be connected to one micro driver μDriver. As another example, 16 micro LEDs (ED) may be connected to one micro driver μDriver, or 32 micro LEDs (ED) or 64 micro LEDs (ED) may be simultaneously connected to one micro driver μDriver. The micro LED ED may be a micro LED (μLED).

One micro driver μDriver may include a driving transistor TDR and an emission transistor T_{EM}, but the example embodiments of the present disclosure are not limited thereto.

For example, the driving transistor T_{DR} may have a first electrode to which a high potential power voltage VDD is be applied, a second electrode to which a first electrode of the emission transistor T_{EM} is connected, and a gate electrode to which a scan signal SC is applied. The scan signal SC applied to the gate electrode of the driving transistor T_{DR} is a direct current (DC) power and a fixed reference voltage may be applied in every frame, but the example embodiments of the present disclosure are not limited thereto.

The emission transistor T_{EM} may have the first electrode to which the second electrode of the driving transistor T_{DR} is connected, a second electrode to which the micro LED ED is connected, and a gate electrode to which the emission signal EM is applied. The emission signal EM applied to the gate electrode of the emission transistor T_{EM} may be a pulse width modulation signal which changes in every frame, but the example embodiments of the present disclosure are not limited thereto.

A first electrode of the micro LED ED may be connected to the second electrode of the emission transistor T_{EM} and a second electrode of the micro LED ED may be connected to the ground. For example, the first electrode may be an anode electrode, and the second electrode may be a cathode electrode, but the example embodiments of the present disclosure are not limited thereto.

Each of the driving transistor T_{DR} and the emission transistor T_{EM} may be an n type transistor or a p type transistor.

The driving transistor T_{DR} may be turned on by a scan signal SC applied from the timing controller (T-CON) to the micro driver μDriver and the emission transistor T_{EM} may be turned on by the emission signal EM. By doing this, the driving current is applied to the micro LED ED via the driving transistor T_{DR} and the emission transistor T_{EM} by the high potential power voltage VDD applied to the first electrode of the driving transistor T_{DR} so that the micro LED ED may emit light.

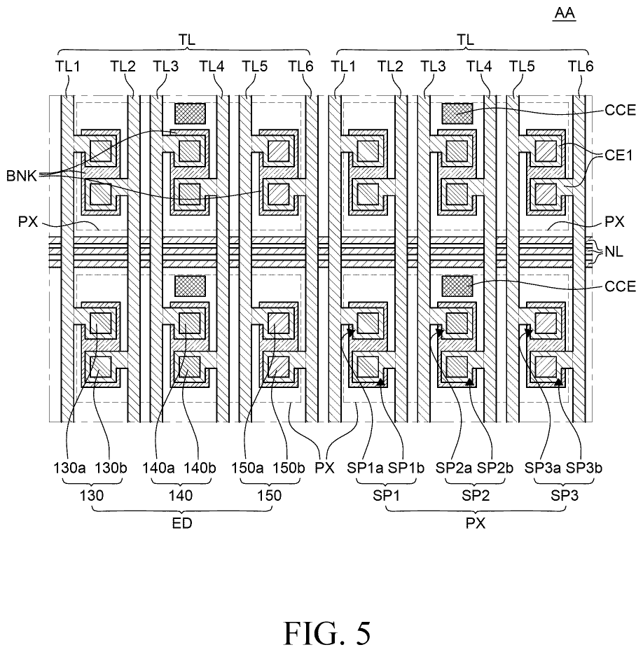

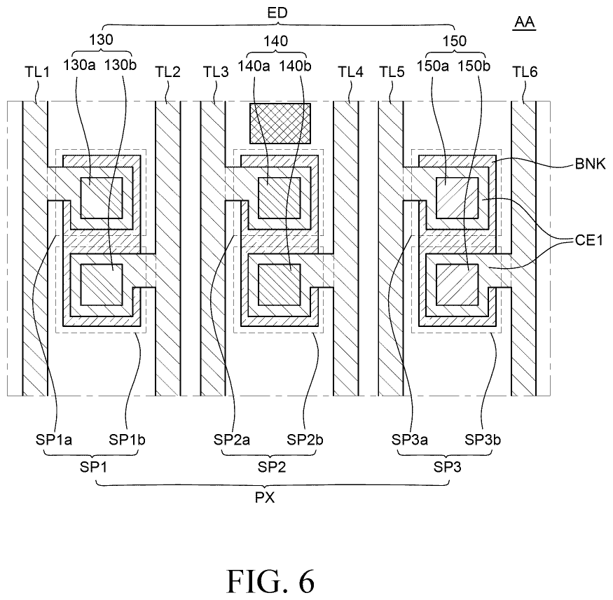

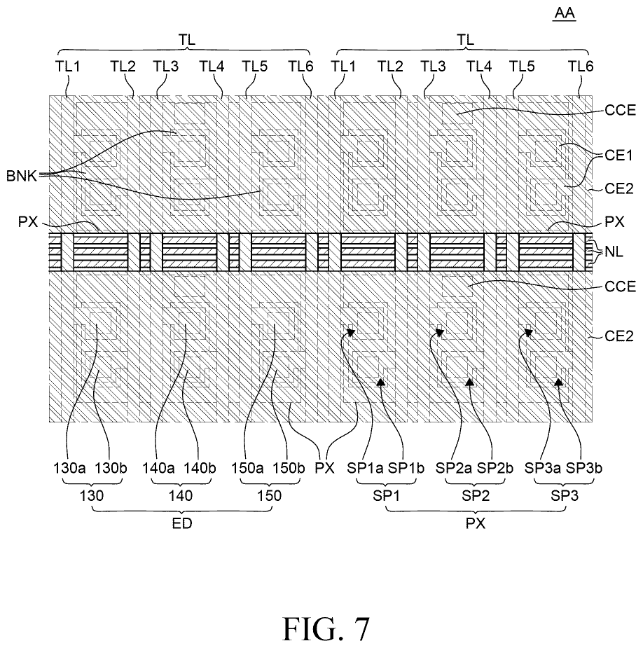

FIGS. 5 to 7 are plan views of a display apparatus according to an example embodiment of the present disclosure; For example, FIG. 5 is an enlarged plan view of an active area including a plurality of pixels. For example, FIG. 6 is an enlarged plan view of an active area including one pixel. For example, FIG. 7 is an enlarged plan view of an active area including a plurality of pixels. In FIGS. 5 and 6, only a plurality of signal lines TL, a plurality of communication lines NL, a plurality of first electrodes CE1, a plurality of banks BNK, and a plurality of micro LEDs (ED) are illustrated, but the example embodiments of the present disclosure are not limited thereto. FIG. 7 is an enlarged plan view in which a plurality of second electrodes CE2 is additionally disposed to FIG. 5.

As shown in FIGS. 5 and 6, a plurality of pixels PX which is configured by a plurality of sub pixels may be disposed in the active area AA. Each of the plurality of sub pixels includes a micro LED ED and independently may emit light. The plurality of sub pixels may be disposed in a matrix by forming a plurality of rows and a plurality of columns, but the example embodiments of the present disclosure are not limited thereto.

The plurality of sub pixels may include a first sub pixel SP1, a second sub pixel SP2, and a third sub pixel SP3. For example, any one of the first sub pixel SP1, the second sub pixel SP2, and the third sub pixel SP3 may be a red sub pixel, another may be a green sub pixel, and the third may be a blue sub pixel. The types of the plurality of sub pixels are illustrative, but the example embodiments of the present disclosure are not limited thereto.

Each of the plurality of pixels PX may include one or more first sub pixels SP1, one or more second sub pixels SP2, and one or more third sub pixels SP3. For example, one pixel PX may include one pair of first sub pixels SP1, one pair of second sub pixels SP2, and one pair of third sub pixels SP3. One pair of first sub pixels SP1 may be configured by a 1-1-th sub pixel SP1a and a 1-2-th sub pixel SP1b. One pair of second sub pixels SP2 may be configured by a 2-1-th sub pixel SP2a and a 2-2-th sub pixel SP2b. One pair of third sub pixels SP3 may be configured by a 3-1-th sub pixel SP3a and a 3-2-th sub pixel SP3b. For example, one pixel PX may include a 1-1-th sub pixel SP1a and a 1-2-th sub pixel SP1b, a 2-1-th sub pixel SP2a and a 2-2-th sub pixel SP2b, and a 3-1-th sub pixel SP3a and a 3-2-th sub pixel SP3b, but the example embodiments of the present disclosure are not limited thereto.

The plurality of sub pixels which forms one pixel PX may be disposed in various ways. For example, in one pixel PX, one pair of first sub pixels SP1 may be disposed on the same column, one pair of second sub pixels SP2 may be disposed on the same column, and one pair of third sub pixels SP3 may be disposed on the same column. The first sub pixels SP1, the second sub pixels SP2, and the third sub pixels SP3 may be disposed on the same row. A number and a placement of the plurality of sub pixels which configures one pixel PX are illustrative, but the example embodiments of the present disclosure are not limited thereto.

The plurality of signal lines TL may be disposed in an area between the plurality of sub pixels. The plurality of signal lines TL may extend in the column direction between the plurality of sub pixels. The plurality of signal lines TL may be wiring lines which transmit an anode voltage from the pixel driving circuit PD to the plurality of sub pixels. For example, the plurality of signal lines TL may be electrically connected to the plurality of pixel driving circuits PD and the first electrodes CE1 of the plurality of sub pixels. The anode voltage output from the pixel driving circuit PD may be transmitted to the first electrode CE1 of the plurality of sub pixels through the plurality of signal lines TL. For example, the first electrode CE1 may be an electrode which is electrically connected to the anode electrode 134 of the micro LED ED. Therefore, the anode voltage from the signal line TL may be transmitted to the anode electrode 134 of the micro LED ED through the first electrode CE1.

Accordingly, instead of the plurality of transistors and storage capacitors formed in each of the plurality of sub pixels, a pixel driving circuit PD in which a plurality of pixel circuits is integrated is used to simplify the structure of the display apparatus 1000. Further, a circuit which is disposed in each of the plurality of sub pixels is integrated in one pixel driving circuit PD so that highly efficient low power driving may be possible.

The plurality of signal lines TL may include a first signal line TL1, a second signal line TL2, a third signal line TL3, a fourth signal line TL4, a fifth signal line TL5, and a sixth signal line TL6. The first signal line TL1 and the second signal line TL2 may be electrically connected to one pair of first sub pixels SP1, respectively. The third signal line TL3 and the fourth signal line TL4 may be electrically connected to one pair of second sub pixels SP2, respectively. The fifth signal line TL5 and the sixth signal line TL6 may be electrically connected to one pair of third sub pixels SP3, respectively.

The first signal line TL1 is disposed on one of one pair of first sub pixels SP1 and the second signal line TL2 may be disposed on the other one of one pair of first sub pixels SP1. The first signal line TL1 may be electrically connected to one first sub pixel SP1, between one pair of first sub pixels SP1, for example, to the first electrode CE1 of the 1-1-th sub pixel SP1a. The second signal line TL2 may be electrically connected to the other first sub pixel SP1, between one pair of first sub pixels SP1, for example, to the first electrode CE1 of the 1-2-th sub pixel SP1b.

The third signal line TL3 may be disposed on one of one pair of second sub pixels SP2 and the fourth signal line TL4 may be disposed on the other one of one pair of second sub pixels SP2. For example, the third signal line TL3 may be disposed to be adjacent to the second signal line TL2. The third signal line TL3 may be electrically connected to one second sub pixel SP2, between one pair of second sub pixels SP2, for example, to the first electrode CE1 of the 2-1-th sub pixel SP2a. The fourth signal line TL4 may be electrically connected to the other second sub pixel SP2, between one pair of second sub pixels SP2, for example, to the first electrode CEL of the 2-2-th sub pixel SP2b.

The fifth signal line TL5 is disposed on one of one pair of third sub pixels SP3 and the sixth signal line TL6 may be disposed on the other one of one pair of third sub pixels SP3. For example, the fifth signal line TL5 may be disposed to be adjacent to the fourth signal line TL4. The sixth signal line TL6 may be disposed to be adjacent to the first signal line TL1 connected to the adjacent pixel PX. The fifth signal line TL5 may be electrically connected to one third sub pixel SP3, between one pair of third sub pixels SP3, for example, to the first electrode CE1 of the 3-1-th sub pixel SP3a. The sixth signal line TL6 may be electrically connected to the other third sub pixel SP3, between one pair of third sub pixels SP3, for example, to the first electrode CE1 of the 3-2-th sub pixel SP3b.

The plurality of signal lines TL may be formed of a conductive material. For example, the plurality of signal lines TL may be configured by a conductive material, such as titanium (Ti), aluminum (Al), copper (Cu), molybdenum (Mo), nickel (Ni), chrome (Cr), indium tin oxide (ITO), indium zinc oxide (IZO), indium gallium zinc oxide (IGZO). However, the example embodiments of the present disclosure are not limited thereto. As another example, the plurality of signal lines TL may be formed with a multi-layered structure of conductive materials. For example, the plurality of signal lines TL may be formed with a multi-layered structure of titanium (Ti)/aluminum (Al)/titanium (Ti)/indium tin oxide (ITO), but the example embodiments of the present disclosure are not limited thereto.

A plurality of communication lines NL may be disposed in an area between the plurality of pixels PX. The plurality of communication lines NL may be disposed to extend in the row direction in an area between the plurality of pixels PX. The plurality of communication lines NL may be disposed in the area between the plurality of second electrodes CE2 and may not overlap the plurality of second electrodes CE2. For example, the plurality of communication lines NL may be wiring lines used for short distance communication, such as near field communication (NFC). The plurality of communication lines NL may serve as antennas. For example, the plurality of communication lines NL may be a plurality of connection lines, but the example embodiments of the present disclosure are not limited thereto.

According to the present disclosure, a bank BNK may be disposed in each of the plurality of sub pixels. The plurality of banks BNK may be structures in which the plurality of micro LEDs (ED) is seated. The plurality of banks BNK may guide a position of the plurality of micro LEDs (ED) during a transfer process of transferring the plurality of micro LEDs (ED) to the display apparatus 1000. The plurality of micro LEDs (ED) may be transferred onto the plurality of banks BNK in the transfer process of the plurality of micro LEDs (ED). The plurality of banks BNK may be a bank pattern or a pattern structure, but the example embodiments of the present disclosure are not limited thereto.

A bank BNK of the first sub pixel SP1, a bank BNK of the second sub pixel SP2, and a bank BNK of the third sub pixel SP3 may be disposed to be spaced apart from each other. The bank BNK of the first sub pixel SP1, the bank BNK of the second sub pixel SP2, and the bank BNK of the third sub pixel SP3 may be configured to be separated from each other. Therefore, the banks BNK of the first sub pixel SP1, the second sub pixel SP2, and the third sub pixel SP3 to which different types of micro LEDs (ED) are transferred may be easily identified.

The bank BNK of the 1-1-th sub pixel SP1a and the bank BNK of the 1-2-th sub pixel SP1b may be connected to each other or spaced apart or separated from each other. For example, in consideration of a design, such as a transfer process requirement or specification, the bank BNK of the 1-1-th sub pixel SP1a and the bank BNK of the 1-2-th sub pixel SP1b in which the same type of micro LED ED is disposed may be connected to each other or spaced apart or separated from each other. The bank BNK of the 2-1-th sub pixel SP2a and the bank BNK of the 2-2-th sub pixel SP2b may be connected to each other, spaced apart or separated from each other. The bank BNK of the 3-1-th sub pixel SP3a and the bank BNK of the 3-2-th sub pixel SP3b may be connected to each other, spaced apart or separated from each other. Accordingly, the banks BNK of one pair of first sub pixels SP1, the banks BNK of one pair of second sub pixels SP2, and the banks BNK of one pair of third sub pixels SP3 may be formed in various forms, but the example embodiments of the present disclosure are not limited thereto.

For example, the plurality of banks BNK may be formed of an organic insulating material. The plurality of banks BNK may be configured by a single layer or a double layer of an organic insulating material. For example, the plurality of banks BNK may be configured by a photo resist, polyimide (PI), or acrylic material, but the example embodiments of the present disclosure are not limited thereto.

The first electrode CE1 may be disposed in each of the plurality of sub pixels. The first electrode CE1 may be disposed on the bank BNK. The first electrode CE1 may be electrically connected to one signal line TL, among the plurality of signal lines TL. At least a part of the first electrode CE1 extends to the outside of the bank BNK to be electrically connected to the signal line TL which is the most adjacent to the first electrode CE1. For example, a part of the first electrode CE1 of the 1-1-th sub pixel SP1a extends to one area of the 1-1-th sub pixel SP1a to be electrically connected to the first signal line TL1. A part of the first electrode CE1 of the 1-2-th sub pixel SP1b extends to the other area of the 1-2-th sub pixel SP1b to be electrically connected to the second signal line TL2. A part of the first electrode CE1 of the 2-1-th sub pixel SP2a extends to one area of the 2-1-th sub pixel SP2a to be electrically connected to the third signal line TL3. A part of the first electrode CE1 of the 2-2-th sub pixel SP2b extends to the other area of the 2-2-th sub pixel SP2b to be electrically connected to the fourth signal line TL4. A part of the first electrode CE1 of the 3-1-th sub pixel SP3a extends to one area of the 3-1-th sub pixel SP3a to be electrically connected to the fifth signal line TL5. A part of the first electrode CE1 of the 3-2-th sub pixel SP3b extends to the other area of the 3-2-th sub pixel SP3b to be electrically connected to the sixth signal line TL6.

The first electrode CE1 is electrically connected to the anode electrode 134 of the micro LED ED and may transmit an anode voltage from the pixel driving circuit PD to the micro LED ED through the signal line TL. Different voltages may be applied to the first electrodes CE1 of the plurality of sub pixels depending on the image to be displayed. For example, different voltages may be applied to the first electrodes CE1 of the plurality of sub pixels. Therefore, the first electrode CE1 may be a pixel electrode, but the example embodiments of the present disclosure are not limited thereto.

The first electrode CE1 may be configured by a conductive material. For example, the first electrode CE1 may be integrally configured with the plurality of signal lines TL. For example, the first electrode CE1 may be configured by the same conductive material as the plurality of signal lines TL, but the example embodiments of the present disclosure are not limited thereto. For example, the first electrode CE1 may be configured by a conductive material, such as titanium (Ti), aluminum (Al), copper (Cu), molybdenum (Mo), nickel (Ni), chrome (Cr), indium tin oxide (ITO), indium zinc oxide (IZO), indium gallium zinc oxide (IGZO). However, the example embodiments of the present disclosure are not limited thereto. As another example, the first electrode CE1 may be configured by a multi-layered structure of conductive materials. For example, the plurality of first electrodes CE1 may be configured by a multi-layered structure of titanium (Ti)/aluminum (Al)/titanium (Ti)/indium tin oxide (ITO), but the example embodiments of the present disclosure are not limited thereto.

The micro LED ED may be disposed in each of the plurality of sub pixels. The plurality of micro LEDs (ED) may be any one of a light-emitting diode (LED) or a micro light-emitting diode (micro LED), but the example embodiments of the present disclosure are not limited thereto. The plurality of micro LEDs (ED) may be disposed on the bank BNK and the first electrode CE1. The plurality of micro LEDs (ED) is disposed on the first electrode CE1 and may be electrically connected to the first electrode CE1. Accordingly, the micro LED ED is applied with an anode voltage from the pixel driving circuit PD through the signal line TL and the first electrode CE1 to emit light.

The plurality of micro LEDs (ED) may include a first micro LED 130, a second micro LED 140, and a third micro LED 150. The first micro LED 130 may be disposed in the first sub pixel SP1. The second micro LED 140 may be disposed in the second sub pixel SP2. The third micro LED 150 may be disposed in the third sub pixel SP3. For example, any one of the first micro LED 130, the second micro LED 140, and the third micro LED 150 may be a red micro LED, another may be a green micro LED, and the third may be a blue micro LED, but the example embodiments of the present disclosure are not limited thereto. Therefore, red light, green light, and blue light emitted from the plurality of micro LEDs (ED) are combined to implement various color light including white. The types of the plurality of micro LEDs (ED) are illustrative, but the example embodiments of the present disclosure are not limited thereto.

The first micro LED 130 may include a 1-1-th micro LED 130a disposed in the 1-1-th sub pixel SP1a and a 1-2-th micro LED 130b disposed in the 1-2-th sub pixel SP1b. The second micro LED 140 may include a 2-1-th micro LED 140a disposed in the 2-1-th sub pixel SP2a and a 2-2-th micro LED 140b disposed in the 2-2-th sub pixel SP2b. The third micro LED 150 may include a 3-1-th micro LED 150a disposed in the 3-1-th sub pixel SP3a and a 3-2-th micro LED 150b disposed in the 3-2-th sub pixel SP3b.

As shown in FIGS. 5, 6 and 7 together, the second electrode CE2 may be disposed in each of the plurality of sub pixels. The second electrode CE2 may be disposed on the micro LED ED. The second electrode CE2 may be electrically connected to the pixel driving circuit PD through the plurality of contact electrodes CCE.

For example, the second electrode CE2 is electrically connected to the cathode electrode 135 of the micro LED ED to transmit a cathode voltage from the pixel driving circuit PD to the micro LED ED. The same cathode voltage may be applied to the second electrodes CE2 of the plurality of sub pixels. For example, the same voltage may be applied to the second electrode CE2 of each of the plurality of sub pixels and the cathode electrode 135 of the micro LED ED. Therefore, the second electrode CE2 may be a common electrode, but the example embodiments of the present disclosure are not limited thereto.

At least some of the plurality of sub pixel may share the second electrode CE2. At least some of the second electrodes CE2 of the plurality of sub pixels may be electrically connected to each other. As the same voltage is applied to the second electrode CE2, the second electrodes CE2 of at least some of sub pixels may be shared. For example, the second electrodes CE2 of at least some pixels PX, among the plurality of pixels PX disposed on the same row, may be connected to each other. For example, one second electrode CE2 may be disposed in the plurality of pixels PX. One second electrode CE2 may be disposed in every n sub pixels.

For example, some of the second electrodes CE2 of the plurality of sub pixels may be spaced apart or separated from each other. For example, a second electrode CE2 connected to pixels PX in a n-th row and a second electrode CE2 connected to pixels PX in a n+1-th row may be spaced apart or separated from each other. For example, the plurality of second electrodes CE2 may be spaced apart from each other with the plurality of communication lines NL extending in the row direction therebetween. Accordingly, the number of the plurality of sub pixels may be larger than the number of the plurality of second electrodes CE2. As another example, all the second electrodes CE2 of the plurality of sub pixels are connected to each other so that only one second electrode CE2 may be disposed on the substrate 110, but the example embodiments of the present disclosure are not limited thereto.

The plurality of second electrodes CE2 may be configured by a transparent conductive material, but the example embodiments of the present disclosure are not limited thereto. The plurality of second electrodes CE2 is configured by a transparent conductive material so that light emitted from the micro LED ED travels toward the top of the second electrode CE2. For example, the second electrode CE2 may be configured by a transparent conductive material, such as indium tin oxide (ITO), indium zinc oxide (IZO), indium gallium zinc oxide (IGZO), but the example embodiments of the present disclosure are not limited thereto.

A plurality of contact electrodes CCE may be disposed on the substrate 110. For example, the plurality of contact electrodes CCE may be disposed to be spaced apart from the plurality of banks BNK and the plurality of signal lines TL. Each of the plurality of second electrodes CE2 may overlap at least one contact electrode CCE. For example, one second electrode CE2 may overlap a plurality of contact electrodes CCE.

For example, the plurality of contact electrodes CCE may be electrically connected to the plurality of second electrodes CE2. The plurality of contact electrodes CCE is disposed between the substrate 110 and the plurality of second electrodes CE2 to transmit a cathode voltage from the pixel driving circuit PD to the second electrode CE2.

For example, when a micro LED ED is used, a plurality of micro LEDs is formed on a wafer and the micro LED is transferred onto the substrate 110 of the display apparatus 1000 to manufacture the display apparatus 1000. However, during the process of transferring the plurality of micro LEDs (ED) having a micro size from the wafer to the substrate 110, various defects may be caused. For example, in some sub pixel, a non-transfer defect in which the micro LED ED is not transferred may occur and in the other sub pixel, a defect that the micro LED ED is transferred in a wrong position may occur due to the alignment error. Further, even though the transfer process is normally performed, the transferred micro LED ED may be defective. Accordingly, in consideration of the defects during the transfer process of the plurality of micro LEDs (ED), a plurality of same type micro LEDs (ED) may be transferred into one sub pixel. A lighting test for the plurality of micro LEDs (ED) is performed and only one micro LED ED which is finally determined to be normal may be used.

For example, the 1-1-th micro LED 130a and the 1-2-th micro LED 130b are transferred to one pixel PX together and defects thereof may be tested. If both the 1-1-th micro LED 130a and the 1-2-th micro LED 130b are determined to be normal, only the 1-1-th micro LED 130a is used, but the 1-2-th micro LED 130b may be not used. As another example, if only the 1-2-th micro LED 130b among the 1-1-th micro LED 130a and the 1-2-th micro LED 130b is determined to be normal, the 1-1-th micro LED 130a is not used, but only the 1-2-th micro LED 130b may be used. Accordingly, even though the plurality of same type micro LEDs (ED) is transferred to one pixel PX, finally, only one micro LED ED may be used.

Therefore, any one of one pair of micro LEDs (ED) is a main (or primary) micro LED ED and the other micro LED ED may be a redundancy micro LED ED. The redundancy micro LED ED may be an extra micro LED ED which is transferred to prepare for a defect of the main micro LED (ED). When the main micro LED ED is defective, the redundancy micro LED ED may be used instead. Accordingly, the main micro LED ED and the redundancy micro LED ED are transferred together to one pixel PX so that the degradation of the display quality due to the defects of the main micro LED ED and the redundancy micro LED ED may be minimized or suppressed.

For example, a 1-1-th micro LED 130a, a 2-1-th micro LED 140a, and a 3-1-th micro LED 150a which are transferred into one pixel PX are used as main micro LEDs (ED) and a 1-2-th micro LED 130b, a 2-2-th micro LED 140b, and a 3-2-th micro LED 150b may be used as redundancy micro LEDs (ED).

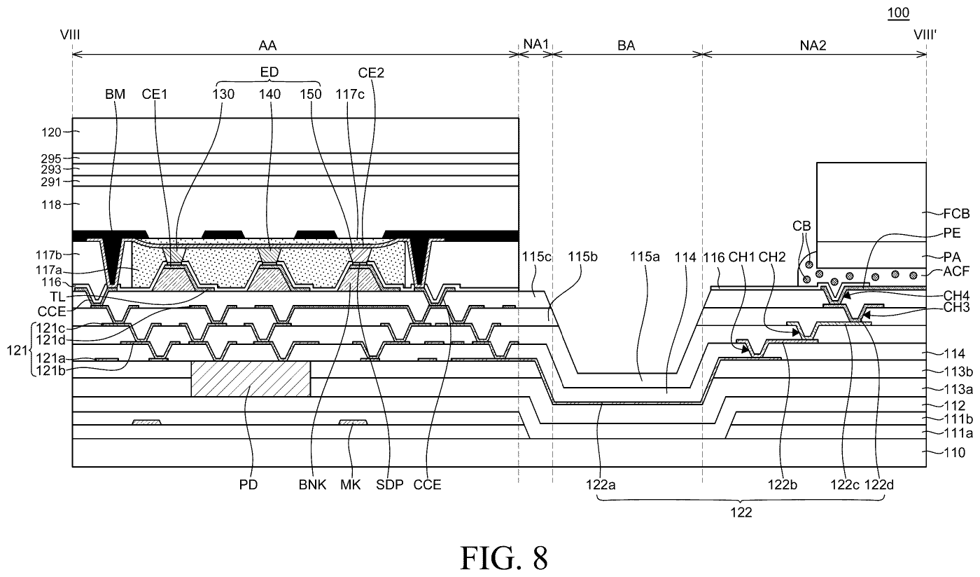

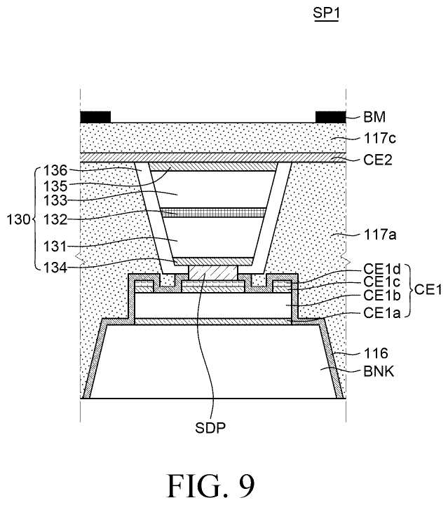

FIG. 8 is a cross-sectional view taken along VIII-VIII′ of FIG. 3. FIG. 9 is a cross-sectional view of a display apparatus according to an example embodiment of the present disclosure. For example, FIG. 8 is a cross-sectional view of an active area AA, a first non-active area NA1, a bending area BA, and a second non-active area NA2. For example, FIG. 9 is an enlarged cross-sectional view of a first sub pixel. In the meantime, for the convenience of illustration, in FIG. 3, it is illustrated that a cross-sectional line of VIII-VIII′ and a driving line VL and a link line LL do not overlap, but the cross-sectional line VIII-VIII′ of FIG. 3 is provided to represent the same position as the adjacent driving line VL and link line LL.

As shown in FIG. 8, a first buffer layer 111a and a second buffer layer 111b may be disposed in the remaining area of the substrate 110 excluding the bending area BA.

The first buffer layer 111a and the second buffer layer 111b may be disposed in the active area AA, the first non-active area NA1, and the second non-active area NA2. The first buffer layer 111a and the second buffer layer 111b may reduce permeation of moisture or impurities through the substrate 110. The first buffer layer 111a and the second buffer layer 111b may be formed of an inorganic insulating material. For example, the first buffer layer 111a and the second buffer layer 111b may be configured by a single layer or multiple layers of silicon oxide (SiOx) or silicon nitride (SiNx), but the example embodiments of the present disclosure are not limited thereto.

For example, the first buffer layer 111a and the second buffer layer 111b on the bending area BA may be partially removed. A top surface of the substrate 110 located in the bending area BA may be exposed from the first buffer layer 111a and the second buffer layer 111b. The first buffer layer 111a and the second buffer layer 111b which are formed of an inorganic insulating material are removed from the bending area BA to minimize or suppress cracks of the first buffer layer 111a and the second buffer layer 111b which may be generated during the bending.

A plurality of alignment keys MK may be disposed between the first buffer layer 111a and the second buffer layer 111b. The plurality of alignment keys MK may be configured to identify a position of the pixel driving circuit PD during the manufacturing process of the display apparatus 1000. For example, the plurality of alignment keys MK may be configured to align a position of the pixel driving circuit PD which is transferred onto the adhesive layer 112. As another example, the plurality of alignment keys MK may be omitted.

The adhesive layer 112 may be disposed on the second buffer layer 111b. The adhesive layer 112 may be disposed in the active area AA, the first non-active area NA1, the bending area BA, and the second non-active area NA2. As another example, in the non-active area NA including the bending area BA, at least a part of the adhesive layer 112 may be removed. For example, the adhesive layer 112 may be formed of any one of adhesive polymer, epoxy resin, UV curable resin, polyimide based resin, acrylate based resin, urethane based resin, and polydimethylsiloxane (PDMS), but the example embodiments of the present disclosure are not limited thereto.

The pixel driving circuit PD may be disposed on the adhesive layer 112 in the active area AA. When the pixel driving circuit PD is implemented as a driver, the driver may be mounted on the adhesive layer 112 by the transfer process, but the example embodiments of the present disclosure are not limited thereto.

A first protection layer 113a and a second protection layer 113b may be disposed on the adhesive layer 112. For example, the first protection layer 113a and the second protection layer 113b may be disposed so as to enclose the side surface of the pixel driving circuit PD, but the example embodiments of the present disclosure are not limited thereto. For example, the second protection layer 113b may be disposed so as to cover at least a part of a top surface of the pixel driving circuit PD. For example, at least one of the first protection layer 113a and the second protection layer 113b of the protection layer 113 disposed on the bending area BA may be omitted. For example, the first protection layer 113a is entirely disposed in the active area AA and the non-active area NA and the second protection layer 113b may be partially disposed in the active area AA, the first non-active area NA1, and the second non-active area NA2. For example, a part of the second protection layer 113b in the bending area BA may be removed, but the example embodiments of the present disclosure are not limited thereto.

The first protection layer 113a and the second protection layer 113b may be configured by an organic insulating material, but the example embodiments of the present disclosure are not limited thereto. For example, the first protection layer 113a and the second protection layer 113b may be configured by a photo resist, polyimide (PI), or photo acrylic material, but the example embodiments of the present disclosure are not limited thereto. For example, the first protection layer 113a and the second protection layer 113b may be overcoating layers or insulating layers, but the example embodiments of the present disclosure are not limited thereto.

According to the present disclosure, in the active area AA, the plurality of first connection lines 121 may be disposed on the second protection layer 113b. The plurality of first connection lines 121 may be wiring lines which electrically connect the pixel driving circuit PD to the other component. For example, the pixel driving circuit PD may be electrically connected to the plurality of signal lines TL and the plurality of contact electrodes CCE through the plurality of first connection lines 121. For example, the plurality of first connection lines 121 may include a 1-1-th connection line 121a, a 1-2-th connection line 121b, a 1-3-th connection line 121c, and a 1-4-th connection line 121b, but the example embodiments of the present disclosure are not limited thereto.

For example, the plurality of 1-1-th connection lines 121a may be disposed on the second protection layer 113b. The plurality of 1-1-th connection lines 121a may be electrically connected to the pixel driving circuit PD. The plurality of 1-1-th connection lines 121a may transmit a voltage output from the pixel driving circuit PD to the first electrode CEL or the second electrode CE2.

For example, a third protection layer 114 may be disposed on the second protection layer 113b. The third protection layer 114 may be entirely disposed in the active area AA and the non-active area NA. In the bending area BA, the third protection layer 114 may cover a side surface of the second protection layer 113b and the top surface of the first protection layer 113a. The third protection layer 114 may be configured by an organic insulating material. For example, the third protection layer 114 may be configured by a photo resist, polyimide (PI), or photo acrylic material, but the example embodiments of the present disclosure are not limited thereto. For example, the first protection layer 113a, the second protection layer 113b, and the third protection layer 114 may be configured by the same material, but the example embodiments of the present disclosure are not limited thereto.

The plurality of 1-2-th connection lines 121b may be disposed on the third protection layer 114. The plurality of 1-2-th connection lines 121b may be indirectly or directly connected to the pixel driving circuit PD. For example, a part of the 1-2-th connection line 121b may be directly connected to the pixel driving circuit PD through a contact hole of the third protection layer 114. The other part of the 1-2-th connection line 121b may be electrically connected to the 1-1-th connection line 121a through the contact hole of the third protection layer 114, but the example embodiments of the present disclosure are not limited thereto. A voltage output from the pixel driving circuit PD may be transmitted to the first electrode CE1 or the second electrode CE2 through a connection line other than the plurality of 1-2-th connection lines 121b.

The first insulating layer 115a may be disposed on the plurality of 1-2-th connection lines 121b. The first insulating layer 115a may be entirely disposed in the active area AA and the non-active area NA, but the example embodiments of the present disclosure are not limited thereto. The first insulating layer 115a is configured by an organic insulating material, but the example embodiments of the present disclosure are not limited thereto. For example, the first insulating layer 115a may be configured by a photo resist, polyimide (PI), or photo acrylic material, but the example embodiments of the present disclosure are not limited thereto.

The plurality of 1-3-th connection lines 121c may be disposed on the first insulating layer 115a. The plurality of 1-3-th connection lines 121c may be electrically connected to the plurality of 1-2-th connection lines 121b. For example, the 1-3-th connection lines 121c may be electrically connected to the 1-2-th connection line 121b through a contact hole of the first insulating layer 115a.

The second insulating layer 115b may be disposed on the plurality of 1-3-th connection lines 121c. The second insulating layer 115b may be disposed in a remaining area excluding the bending area BA, but the example embodiments of the present disclosure are not limited thereto. The second insulating layer 115b may be disposed in the active area AA, the first non-active area NA1, and the second non-active area NA2, but the example embodiments of the present disclosure are not limited thereto. For example, a part of the second insulating layer 115b disposed in the bending area BA may be removed. The second insulating layer 115b may be configured by an organic insulating material, but the example embodiments of the present disclosure are not limited thereto. For example, the second insulating layer 115b is configured by a photo resist, polyimide (PI), or photo acrylic material, but the example embodiments of the present disclosure are not limited thereto.

The plurality of 1-4-th connection lines 121d may be disposed on the second insulating layer 115b. The plurality of 1-4-th connection lines 121d may be electrically connected to the plurality of 1-3-th connection lines 121c. For example, the 1-4-th connection lines 121d may be electrically connected to the 1-3-th connection line 121c through a contact hole of the second insulating layer 115b.

According to the present disclosure, in the non-active area NA, the plurality of second connection lines 122 may be disposed on the second protection layer 113b. The plurality of second connection lines 122 may be wiring lines which transmit a signal transmitted from the flexible circuit board (or flexible film) FCB and the printed circuit board 160 (see FIG. 1) to the pad unit PAD to the pixel driving circuit PD of the active area AA. For example, the plurality of second connection lines 122 is electrically connected to the plurality of pad electrodes PE to be applied with a signal from the flexible circuit board (or flexible film) FCB and the printed circuit board.

For example, the plurality of second connection lines 122 extends toward the active area AA from the pad unit PAD to transmit a signal to the wiring line of the active area AA. In this case, the plurality of second connection lines 122 may serve as a link line LL. The plurality of second connection lines 122 may include a 2-1-th connection line 122a, a 2-2-th connection line 122b, a 2-3-th connection line 122c, and a 2-4-th connection line 122d.

In the meantime, the 2-1-th connection line 122a, the 2-2-th connection line 122b, the 2-3-th connection line 122c, and the 2-4-th connection line 122d may be dispersed so as to overlap each other in only a minimum area. For example, the 2-1-th connection line 122a, the 2-2-th connection line 122b, the 2-3-th connection line 122c, and the 2-4-th connection line 122d may be disposed stepwise. For example, the thicknesses of the plurality of second connection lines 122 in an overlapping area of the 2-1-th connection line 122a and the 2-2-th connection line 122b, in an overlapping area of the 2-2-th connection line 122b and the 2-3-th connection line 122c, and in an overlapping area of the 2-3-th connection line 122c and the 2-4-th connection line 122d may be equal to each other. Therefore, the step caused by the difference in thickness of the second connection line 122 between the overlapping areas of the 2-1-th connection line 122a, the 2-2-th connection line 122b, the 2-3-th connection line 122c, and the 2-4-th connection line 122d and a surrounding area may be relieved. Accordingly, the flatness of the upper portion of the second connection line 122 in which the plurality of pad electrodes PE is disposed may be ensured.

Specifically, the plurality of 2-1-th connection lines 122a may be disposed on the second protection layer 113b. The plurality of 2-1-th connection lines 122a may extend from the second non-active area NA2 to the bending area BA and the first non-active area NA1. The plurality of 2-1-th connection lines 122a may transmit a signal transmitted from the flexible circuit board (or flexible film) FCB and the printed circuit board 160 to the pad unit PAD to the pixel driving circuit PD of the active area AA.

The plurality of 2-2-th connection lines 122b may be disposed on the third protection layer 114. The plurality of 2-2-th connection lines 122b may be disposed in the second non-active area NA2. The 2-2-th connection line 122b may be electrically connected to the 2-1-th connection line 122a through a first contact hole CH1, for example, a contact hole of the third protection layer 114. Accordingly, a signal from the flexible circuit board (or flexible film) FCB and the printed circuit board may be transmitted to the 2-1-th connection line 122a through the 2-2-th connection line 122b.

For example, the 2-2-th connection line 122b overlaps the 2-1-th connection line 122a in only a partial area and may expose a part of the 2-1-th connection line 122a. For example, if it is assumed that between both end portions of the second connection line 122, an end portion more adjacent to the active area AA is one end (for example, a first end) and an end portion more adjacent to an edge of the substrate 110 is the other end (for example, a second end), one end (i.e., the first end) of the 2-2-th connection line 122b may be disposed at the outside more than one end (i.e., the first end) of the 2-1-th connection line 122a. Further, the other end (i.e., the second end) of the 2-2-th connection line 122b may be disposed at the outside more than the other end (i.e., the second end) of the 2-1-th connection line 122a. That is, both end portions of the 2-2-th connection line 122b are respectively disposed at the outside more than both end portions of the 2-1-th connection line 122a so as not to at least partially overlap the 2-1-th connection line 122a, but is not limited thereto. Herein, the outside refers to a side more adjacent to an edge of the substrate 110.

The 2-3-th connection line 122c may be disposed on the first insulating layer 115a. The 2-3-th connection lines 122c may be disposed in the second non-active area NA2. The 2-3-th connection line 122c may be electrically connected to the 2-2-th connection line 122b through a second contact hole CH2, for example, a contact hole of the first insulating layer 115a. Accordingly, a signal from the flexible circuit board (or flexible film) FCB and the printed circuit board may be transmitted to the 2-1-th connection line 122a through the 2-3-th connection line 122c and the 2-2-th connection line 122b.

For example, the 2-3-th connection line 122c overlaps the 2-2-th connection line 122b in only a partial area and may expose a part of the 2-2-th connection line 122b. For example, if it is assumed that between both end portions of the second connection line 122, an end portion more adjacent to the active area AA is one end (for example, a first end) and an end portion more adjacent to an edge of the substrate 110 is the other end (for example, a second end), one end (i.e., the first end) of the 2-3-th connection line 122c may be disposed at the outside more than one end (i.e., the first end) of the 2-2-th connection line 122b. Further, the other end (i.e., the second end) of the 2-3-th connection line 122c may be disposed at the outside more than the other end (i.e., the second end) of the 2-2-th connection line 122b. That is, both end portions of the 2-3-th connection line 122c are respectively disposed at the outside more than both end portions of the 2-2-th connection line 122b so as not to at least partially overlap the 2-2-th connection line 122b, but is not limited thereto.

In the meantime, the 2-3-th connection line 122c may be disposed so as not to overlap the 2-1-th connection line 122a. For example, the 2-3-th connection line 122c may be disposed at the outside of the 2-1-th connection line 122a. That is, one end (i.e., the first end) of the 2-3-th connection line 122c may be disposed at the outside more than the other end (i.e., the second end) of the 2-1-th connection line 122a. Therefore, the second contact hole CH2 which connects the 2-3-th connection line 122c and the 2-2-th connection line 122b may not overlap the 2-1-th connection line 122a, but is not limited thereto.

The 2-4-th connection line 122d may be disposed on the second insulating layer 115b. The 2-4-th connection line 122d may be disposed in the second non-active area NA2. The 2-4-th connection line 122d may be electrically connected to the 2-3-th connection line 122c through a third contact hole CH3, for example, a contact hole of the second insulating layer 115b. Accordingly, a signal from the flexible circuit board (or flexible film) FCB and the printed circuit board 160 may be transmitted to the 2-1-th connection line 122a through the 2-4-th connection line 122d, the 2-3-th connection line 122c, and the 2-2-th connection line 122b.

For example, the 2-4-th connection line 122d overlaps the 2-3-th connection line 122c in only a partial area and may expose a part of the 2-3-th connection line 122c. For example, if it is assumed that between both end portions of the second connection line 122, an end portion more adjacent to the active area AA is one end (for example, a first end) and an end portion more adjacent to an edge of the substrate 110 is the other end (for example, a second end), one end (i.e., the first end) of the 2-4-th connection line 122d may be disposed at the outside more than one end (i.e., the first end) of the 2-3-th connection line 122c. Further, the other end (i.e., a second end) of the 2-4-th connection line 122d may be disposed at the outside more than the other end (i.e., a second end) of the 2-3-th connection line 122c. That is, both end portions of the 2-4-th connection line 122d are respectively disposed at the outside more than both end portions of the 2-3-th connection line 122c so as not to at least partially overlap the 2-3-th connection line 122c, but is not limited thereto.

In the meantime, the 2-4-th connection line 122d may be disposed so as not to overlap the 2-2-th connection line 122b. For example, the 2-4-th connection line 122d may be disposed at the outside of the 2-2-th connection line 122b. That is, one end (i.e., the first end) of the 2-4-th connection line 122d may be disposed at the outside more than the other end (i.e., the second end) of the 2-2-th connection line 122b. Therefore, the third contact hole CH3 which connects the 2-4-th connection line 122d and the 2-3-th connection line 122c may not overlap the 2-2-th connection line 122b. Further, the 2-4-th connection line 122d does not overlap the 2-2-th connection line 122b so that the 2-4-th connection line 122d may not overlap the second contact hole CH2 which connects the 2-2-th connection line 122b and the 2-3-th connection line 122c, but is not limited thereto.

In the meantime, the other end (i.e., the second end) of the 2-2-th connection line 122b is disposed at the outside more than the other end (i.e., the second end) of the 2-1-th connection line 122a and one end (i.e., the first end) of the 2-4-th connection line 122d is disposed at the outside more than the other end (i.e., the second end) of the 2-2-th connection line 122b. Therefore, the 2-4-th connection line 122d may be disposed so as not to overlap the 2-1-th connection line 122a. Therefore, the third contact hole CH3 which connects the 2-4-th connection line 122d and the 2-3-th connection line 122c may not overlap the 2-1-th connection line 122a. Further, the 2-4-th connection line 122d does not overlap the 2-1-th connection line 122a so that the 2-4-th connection line 122d may not overlap the first contact hole CH1 which connects the 2-1-th connection line 122a and the 2-2-th connection line 122b, but the present disclosure is not limited thereto.

The plurality of first connection lines 121 and the plurality of second connection lines 122 may be formed of any one of a conductive material having excellent ductility or various conductive materials used for the active area AA.

For example, the second connection line 122 which is partially disposed in the bending area BA may be configured by a conductive material having excellent ductility, such as gold (Au), silver (Ag), or aluminum (Al), but the example embodiments of the present disclosure are not limited thereto.

For example, the 2-1-th connection line 122a, the 2-2-th connection line 122b, the 2-3-th connection line 122c, the 2-4-th connection line 122d of the plurality of second connection lines 122 are disposed on the same layer as the 1-1-th connection line 121a, the 1-2-th connection line 121b, the 1-3-th connection line 121c, the 1-4-th connection line 121d of the plurality of first connection lines 121 with the same material. However, the example embodiments of the present disclosure are not limited thereto.

For example, the plurality of first connection lines 121 and the plurality of second connection lines 122 may be configured by molybdenum (Mo), chrome (Cr), titanium (Ti), nickel (Ni), neodymium (Nd), copper (Cu), and an alloy of silver (Ag) and magnesium (Mg) or an alloy thereof, but the example embodiments of the present disclosure are not limited thereto.

The third insulating layer 115c may be disposed on the plurality of first connection lines 121 and the plurality of second connection lines 122. The third insulating layer 115c may be disposed in a remaining area excluding the bending area BA, but the example embodiments of the present disclosure are not limited thereto. The third insulating layer 115c may be disposed in the active area AA, the first non-active area NA1, and the second non-active area NA2. A part of the third insulating layer 115c disposed in the bending area BA may be removed. The third insulating layer 115c may be configured by an organic insulating material, but the example embodiments of the present disclosure are not limited thereto. For example, the third insulating layer 115c may be configured by a photo resist, polyimide (PI), or photo acrylic material, but the example embodiments of the present disclosure are not limited thereto.

A plurality of banks BNK may be disposed on the third insulating layer 115c in the active area AA. The plurality of banks BNK may be disposed so as to overlap each of the plurality of sub pixels. One or more same type micro LED ED may be disposed above each of the plurality of banks BNK.

A plurality of signal lines TL may be disposed on the third insulating layer 115c in the active area AA. The plurality of signal lines TL may be disposed in an area between the plurality of banks BNK. For example, the plurality of signal lines TL may be disposed to be adjacent to any one of the plurality of banks BNK.

A plurality of contact electrodes CCE may be disposed on the third insulating layer 115c in the active area AA. The plurality of contact electrodes CCE may supply a cathode voltage from the pixel driving circuit PD to the second electrode CE2.

The first electrode CE1 may be disposed on the bank BNK. For example, the first electrode CE1 may be disposed to extend toward the top of the bank BNK from the adjacent signal line TL. The first electrode CE1 may be disposed on the top surface of the bank BNK and the side surface of the bank BNK. For example, the first electrode CE1 may be disposed to extend from the signal line TL on the top surface of the third insulating layer 115c to the side surface of the bank BNK and the top surface of the bank BNK.

As shown in FIG. 9, the first electrode CE1 may be configured by a plurality of conductive layers. For example, the first electrode CE1 may include a first conductive layer CE1a, a second conductive layer CE1b, a third conductive layer CE1c, and a fourth conductive layer CE1d, but the example embodiments of the present disclosure are not limited thereto.

The first conductive layer CE1a may be disposed on the bank BNK. The second conductive layer CE1b may be disposed on the first conductive layer CE1a. The third conductive layer CE1c may be disposed on the second conductive layer CE1b. The fourth conductive layer CE1d may be disposed on the third conductive layer CE1c. For example, the first conductive layer CE1a, the second conductive layer CE1b, the third conductive layer CE1c, and the fourth conductive layer CE1d may be configured by titanium (Ti), molybdenum (Mo), aluminum (Al), or indium tin oxide (ITO), but the example embodiments of the present disclosure are not limited thereto.

According to the present disclosure, some conductive layer having a good reflection efficiency, among a plurality of conductive layers which configures the first electrode CE1 may be configured as an alignment key for alignment of the micro LED ED and/or a reflective plate. For example, the second conductive layer CE1b, among the plurality of conductive layers of the first electrode CE1, may include a reflective material. For example, the second conductive layer CE1b may include aluminum (Al), but the example embodiments of the present disclosure are not limited thereto. Therefore, the second conductive layer CE1b may be configured as a reflective plate. Further, the second conductive layer CE1b has a high reflection efficiency to be easily identified during the manufacturing process so that a position of the micro LED ED or a transfer position may be aligned based on the second conductive layer CE1b.

For example, in order to configure the second conductive layer CE1b as a reflective plate, the third conductive layer CE1c and the fourth conductive layer CE1d which cover the second conductive layer CE1b may be partially removed or etched. For example, a part of the third conductive layer CE1c and the fourth conductive layer CE1d disposed on the bank BNK is removed or etched to expose a top surface of the second conductive layer CE1b. For example, a center portion and an edge portion (or a boundary portion) of the third conductive layer CE1c and the fourth conductive layer CE1d in which a solder pattern SDP is disposed remain and the remaining portion excluding the portions may be removed. For example, an edge portion (or a boundary portion) of each of the third conductive layer CE1c formed of titanium (Ti) and the fourth conductive layer CE1d formed of indium tin oxide (ITO) may not be etched. Therefore, corrosion of another conductive layer of the first electrode CE1 caused by tetramethylammonium hydroxide (TMAH) solution which is used for the mask process of the first electrode CE1 may be suppressed.

According to the present disclosure, the first conductive layer CE1a and the third conductive layer CE1c may include titanium (Ti) or molybdenum (Mo). The second conductive layer CE1b includes aluminum (Al). The fourth conductive layer CE1d may include a transparent conductive oxide layer, such as indium tin oxide (ITO) or indium zinc oxide (IZO), which is adhesive to the solder pattern SPD, and has anti-corrosion and acid resistance, but the example embodiments of the present disclosure are not limited thereto.

The first conductive layer CE1a, the second conductive layer CE1b, the third conductive layer CE1c, and the fourth conductive layer CE1d are sequentially deposited, and then are subject to a photolithographic process and an etching process to be patterned, but the example embodiments of the present disclosure are not limited thereto.

According to the present disclosure, the signal line TL, the contact electrode CCE, and the pad electrode PE disposed on the same layer as the first electrode CE1 may be configured by multiple layers of conductive materials, but the example embodiments of the present disclosure are not limited thereto. For example, the signal line TL, the contact electrode CCE, and the pad electrode PE may be formed of multiple layers of indium tin oxide (ITO)/titanium (Ti)/aluminum (Al)/titanium (Ti), but the example embodiments of the present disclosure are not limited thereto.

According to the present disclosure, in each of the plurality of sub pixels, a solder pattern SDP may be disposed on the first electrode CE1. The solder pattern SDP bonds the micro LED ED to the first electrode CE1 to electrically connect the first electrode CE1 and the micro LED ED. For example, the first electrode CE1 and the anode electrode 134 of the micro LED ED may be electrically connected through eutectic bonding using the solder pattern SDP, but the example embodiments of the present disclosure are not limited thereto.

For example, when the solder pattern SDP is configured by indium (In) and the anode electrode 134 of the micro LED ED is configured by gold (Au), during the transfer process of the micro LED ED, heat and pressure are applied to bond the solder pattern SDP and the anode electrode 134. The micro LED ED may be bonded to the solder pattern SDP and the first electrode CE1 using the eutectic bonding without a separate adhesive material. For example, the solder pattern SDP may be configured by indium (Id), tin (Sn), or an alloy thereof, but the example embodiments of the present disclosure are not limited thereto. For example, the solder pattern SDP may be a bonding pad or an adhesive pad, but the example embodiments of the present disclosure are not limited thereto.

According to the present disclosure, the passivation layer 116 may be disposed on the plurality of signal lines TL, the plurality of first electrodes CE1, the plurality of contact electrodes CCE, and the third insulating layer 115c. For example, the passivation layer 116 may be disposed in the active area AA, the first non-active area NA1, and the second non-active area NA2. A part of the passivation layer 116 disposed in the bending area BA may be removed. A part of the passivation layer 116 which covers a plurality of pad electrodes PE in the second non-active area NA2 may be removed. The passivation layer 116 is disposed so as to cover the remaining area excluding the bending area BA, the plurality of pad electrodes PE, and the area where the solder pattern SDP is disposed to reduce permeation of moisture or impurities entering the micro LED ED. For example, the passivation layer 116 may be configured by a single layer or multiple layers of silicon oxide (SiOx) or silicon nitride (SiNx), but the example embodiments of the present disclosure are not limited thereto. For example, the passivation layer 116 may be a protection layer or an insulating layer, but the example embodiments of the present disclosure are not limited thereto. For example, the passivation layer 116 may include a hole through which the solder pattern SDP is exposed.

In each of the plurality of sub pixels, the micro LED ED may be disposed on the solder pattern SDP. A first micro LED 130 may be disposed in the first sub pixel SP1. A second micro LED 140 may be disposed in the second sub pixel SP2. A third micro LED 150 may be disposed in the third sub pixel SP3.

The micro LED ED may be formed on a silicon wafer using metal organic chemical vapor deposition (MOCVD), chemical vapor deposition (CVD), plasma-enhanced chemical vapor deposition (PECVD), molecular beam epitaxy (MBE), hydride vapor phase epitaxy (HVPE), or a sputtering method. However, the example embodiments of the present disclosure are not limited thereto.

As shown in FIG. 9, the first micro LED 130 may include an anode electrode 134, a first semiconductor layer 131, an active layer 132, a second semiconductor layer 133, a cathode electrode 135, and an encapsulation film 136, but the example embodiments of the present disclosure are not limited thereto. For example, the encapsulation film 136 may not be included in the first micro LED 130.

The first semiconductor layer 131 may be disposed on the solder pattern SDP. The second semiconductor layer 133 may be disposed on the first semiconductor layer 131.

For example, one of the first semiconductor layer 131 and the second semiconductor layer 133 may be implemented by a compound semiconductor, such as a III-V group or a II-VI group and may be doped with an impurity (or dopant). For example, one of the first semiconductor layer 131 and the second semiconductor layer 133 is an n-type impurity doped semiconductor layer and the other one is a p-type impurity doped semiconductor layer, but the example embodiments of the present disclosure are not limited thereto. For example, one or more of the first semiconductor layer 131 and the second semiconductor layer 133 may be a layer in which n-type or p-type impurity is doped on a material, such as gallium nitride (GaN), gallium phosphide (GaP), gallium arsenide phosphide (GaAsP), aluminum gallium indium phosphide (AlGaInP), indium aluminum phosphide (InAlP), aluminum gallium nitride (AlGaN), aluminum indium nitride (AlInN), aluminum indium gallium nitride (AlInGaN), aluminum gallium arsenide (AlGaAs), or gallium arsenide (GaAs). However, the example embodiments of the present disclosure are not limited thereto. For example, the n-type impurity may be silicon (Si), germanium (Ge), selenium (Se), carbon (C), tellurium (Te), or tin (Sn), but the example embodiments of the present disclosure are not limited thereto. For example, the p-type impurity may be magnesium (Mg), zinc (Zn), calcium (Ca), strontium (Sr), barium (Ba), or beryllium (Be), but the example embodiments of the present disclosure are not limited thereto.

For example, each the first semiconductor layer 131 and the second semiconductor layer 133 may be a nitride semiconductor including an n-type impurity or a nitride semiconductor including a p-type impurity, but the example embodiments of the present disclosure are not limited thereto. For example, the first semiconductor layer 131 may be a nitride semiconductor including a p-type impurity and the second semiconductor layer 133 may be a nitride semiconductor including an n-type impurity, but the example embodiments of the present disclosure are not limited thereto.

The active layer 132 may be disposed between the first semiconductor layer 131 and the second semiconductor layer 133. The active layer 132 is supplied with holes and electrons from the first semiconductor layer 131 and the second semiconductor layer 133 to emit light. For example, the active layer 132 may be configured by a single well structure, a multi-well structure, a single quantum well structure, a multi-quantum well (MQW) structure, a quantum dot structure, or a quantum line structure, but the example embodiments of the present disclosure are not limited thereto. For example, the active layer 132 may be configured by indium gallium nitride (InGaN) or gallium nitride (GaN), but the example embodiments of the present disclosure are not limited thereto.

As another example, the active layer 132 may have a multi quantum well (MQW) structure having a well layer and a barrier layer with a band gap higher than the well layer. For example, in the active layer 132, InGaN may be configured as a well layer and an AlGaN layer may be configured as a barrier layer, but the example embodiments of the present disclosure are not limited thereto.

The anode electrode 134 may be disposed between the first semiconductor layer 131 and the solder pattern SDP. For example, the anode electrode 134 may electrically connect the first semiconductor layer 131 and the first electrode CE1. The anode voltage output from the pixel driving circuit PD may be applied to the first semiconductor layer 131 through the signal line TL, the first electrode CE1, and the anode electrode 134. For example, the anode electrode 134 may be configured by a conductive material which may form eutectic bonding with the solder pattern SDP, but the example embodiments of the present disclosure are not limited thereto. For example, the anode electrode 134 may be configured by gold (Au), tin (Sn), tungsten (W), silicon (Si), silver (Ag), titanium (Ti), iridium (Ir), chromium (Cr), indium (In), zinc (Zn), lead (Pb), nickel (Ni), platinum (Pt), copper (Cu), or an alloy thereof, but the example embodiments of the present disclosure are not limited thereto.

The cathode electrode 135 may be disposed on the second semiconductor layer 133. For example, the cathode electrode 135 may electrically connect the second semiconductor layer 133 and the second electrode CE2. A cathode voltage output from the pixel driving circuit PD may be applied to the second semiconductor layer 133 through the contact electrode CCE, the second electrode CE2, and the cathode electrode 135. The cathode electrode 135 may be configured by a transparent conductive material to allow light emitted from the micro LED ED to be directed to the top of the micro LED ED, but the example embodiments of the present disclosure are not limited thereto. For example, the cathode electrode 135 may be configured by a material, such as indium tin oxide (ITO), indium zinc oxide (IZO), indium gallium zinc oxide (IGZO), but the example embodiments of the present disclosure are not limited thereto.

The encapsulation film 136 may be disposed on at least a part of the first semiconductor layer 131, the active layer 132, the second semiconductor layer 133, the anode electrode 134, and the cathode electrode 135. For example, the encapsulation film 136 may enclose at least a part of the first semiconductor layer 131, the active layer 132, the second semiconductor layer 133, the anode electrode 134, and the cathode electrode 135.

For example, the encapsulation film 136 may protect the first semiconductor layer 131, the active layer 132, and the second semiconductor layer 133. For example, the encapsulation film 136 may be disposed on a side surface of the first semiconductor layer 131, a side surface of the active layer 132, and a side surface of the second semiconductor layer 133.

For example, the encapsulation film 136 may be disposed on at least a part of the anode electrode 134 and the cathode electrode 135, for example, on an edge portion (or a boundary portion or one side) of the anode electrode 134 and an edge portion (or a boundary portion or one side) of the cathode electrode 135. At least a part of the anode electrode 134 is exposed from the encapsulation film 136 so that the anode electrode 134 and the solder pattern SDP may be connected. For example, at least a part of the cathode electrode 135 is exposed from the encapsulation film 136 so that the cathode electrode 135 and the second electrode CE2 may be connected. For example, the encapsulation film 136 may be formed of an insulating material, such as silicon nitride (SiNx) or silicon oxide (SiOx), but the example embodiments of the present disclosure are not limited thereto.

As another example, the encapsulation film 136 may have a structure in which a reflective material is dispersed in a resin layer, but the example embodiments of the present disclosure are not limited thereto. For example, the encapsulation film 136 may be manufactured with reflectors with various structures, but the example embodiments of the present disclosure are not limited thereto. Light emitted from the active layer 132 is upwardly reflected by the encapsulation film 136 so that light extraction efficiency may be improved. For example, the encapsulation film 136 may be a reflective layer, but the example embodiments of the present disclosure are not limited thereto.

According to the present disclosure, it is described that the micro LED ED has a vertical type structure, but the example embodiments of the present disclosure are not limited thereto. For example, the micro LED ED may have a lateral structure or a flip-chip structure.

The first micro LED 130 has been described with reference to FIG. 9 and the second micro LED 140 and the third micro LED 150 may have the substantially same structure as the first micro LED 130. For example, the second micro LED 140 and the third micro LED 150 may be substantially the same as the first semiconductor layer 131, the active layer 132, the second semiconductor layer 133, the anode electrode 134, the cathode electrode 135, and the encapsulation film 136 of the first micro LED 130.

According to the present disclosure, in the active area AA, a first optical layer 117a which encloses the plurality of micro LEDs (ED) may be disposed. For example, the first optical layer 117a may be disposed so as to cover the plurality of micro LEDs (ED) and the bank BNK in the area of the plurality of sub pixels. For example, the first optical layer 117a may cover the bank BNK, a part of the passivation layer 116 and between the plurality of micro LEDs (ED). The first optical layer 117a may be disposed or cover between the plurality of micro LEDs (ED) and between the plurality of banks BNK included in one pixel PX. For example, the first optical layer 117a extends in a first row direction and may be spaced apart from each other in a second column direction. For example, the first optical layer 117a may be disposed so as to enclose side portions of the micro LED ED and the bank BNK between the passivation layer 116 and the second electrode CE2, but the example embodiments of the present disclosure are not limited thereto. For example, the first optical layer 117a may be a diffusion layer or a side wall diffusion layer, but the example embodiments of the present disclosure are not limited thereto.

The first optical layer 117a may include an organic insulating material in which micro particles are dispersed, but the example embodiments of the present disclosure are not limited thereto. For example, the first optical layer 117a may be configured by siloxane in which micro particles, such as titanium dioxide (TiO₂) particles, are dispersed, but the example embodiments of the present disclosure are not limited thereto. Light from the plurality of micro LEDs (ED) is scattered by micro particles dispersed in the first optical layer 117a to be emitted to the outside of the display apparatus 1000. Accordingly, the first optical layer 117a may improve extraction efficiency of light emitted from the plurality of micro LEDs (ED).

For example, the first optical layer 117a may be disposed in each of the plurality of pixels PX or disposed in some pixel PX disposed in the same row together, but the example embodiments of the present disclosure are not limited thereto. For example, the first optical layer 117a is disposed in each of the plurality of pixels PX or the plurality of pixels PX may share one first optical layer 117a. As another example, each of the plurality of sub pixels may separately include the first optical layer 117a, but the example embodiments of the present disclosure are not limited thereto.

According to the present disclosure, in the active area AA, a second optical layer 117b may be disposed on the passivation layer 116. For example, the second optical layer 117b may be disposed so as to enclose the first optical layer 117a. For example, the second optical layer 117b may be in contact with a side surface of the first optical layer 117a. For example, the second optical layer 117b may be disposed in an area between the plurality of pixels PX. However, the example embodiments of the present disclosure are not limited thereto. For example, the second optical layer 117b may be a diffusion layer, a diffusion layer window, or a window diffusion layer, but the example embodiments of the present disclosure are not limited thereto.

The second optical layer 117b may be configured by an organic insulating material, but the example embodiments of the present disclosure are not limited thereto. The second optical layer 117b may be configured by the same material as the first optical layer 117a, but the example embodiments of the present disclosure are not limited thereto. For example, the first optical layer 117a may include micro particles, but the second optical layer 117b may not include micro particles. For example, the second optical layer 117b may be configured by siloxane, but the example embodiments of the present disclosure are not limited thereto.

For example, a thickness of the first optical layer 117a may be smaller than a thickness of the second optical layer 117b, but the example embodiments of the present disclosure are not limited thereto. Accordingly, in the plan view, an area in which the first optical layer 117a is disposed may include a concave portion which is inwardly dented from an upper surface of the second optical layer 117b.

According to the present disclosure, the second electrode CE2 may be disposed on the first optical layer 117a and the second optical layer 117b. For example, the second electrode CE2 may be electrically connected to the plurality of contact electrodes CCE through a contact hole of the second optical layer 117b. For example, the second electrode CE2 may be disposed on the plurality of micro LEDs (ED). For example, the second electrode CE2 may include a transparent conductive oxide, such as indium tin oxide (ITO) or indium zinc oxide (IZO), but the example embodiments of the present disclosure are not limited thereto. For example, the second electrode CE2 may be disposed to be in contact with the cathode electrode 135. For example, the second electrode CE2 may overlap the first optical layer 117a. For example, the second electrode CE2 may cover a plane at the outside of the first optical layer 117a.

The second electrode CE2 may continuously extend in a first direction of the substrate 110. Accordingly, the second electrode may be commonly connected to the plurality of pixels PX disposed in the first direction of the substrate 110. For example, the second electrode CE2 may be commonly connected to the plurality of pixels PX.

According to the present disclosure, the second electrode CE2 may continuously extend on the first optical layer 117a, the second optical layer 117b, and the micro LED ED. The area in which the first optical layer 117a is disposed may include a concave portion which is inwardly dented from an upper surface of the second optical layer 117b. Accordingly, the first part of the second electrode CE2 disposed on the first optical layer 117a is disposed along the concave portion so that the first part may be disposed to be lower than the second part of the second electrode CE2 disposed on the second optical layer 117b.

The third optical layer 117c may be disposed on the second electrode CE2. The third optical layer 117c may be disposed so as to overlap the plurality of micro LEDs (ED) and the first optical layer 117a. The third optical layer 117c is disposed above the second electrode CE2 and the plurality of micro LEDs (ED) so that mura which may be generated in a part of the plurality of micro LEDs (ED) may be improved. For example, when the plurality of micro LEDs (ED) is transferred onto the substrate 110 of the display apparatus 1000, an area in which the interval between the plurality of micro LEDs (ED) is not uniform may be caused due to a process deviation. When the interval between the plurality of micro LEDs (ED) is not uniform, an emission area of each of the plurality of micro LEDs (ED) may be not uniformly disposed so that the mura may be visible to a user. Accordingly, the third optical layer 117c which is configured to uniformly diffuse light is configured above the plurality of micro LEDs (ED) so that light emitted from some micro LED ED which is visible as mura may be reduced. Accordingly, light emitted from the plurality of micro LEDs (ED) is uniformly diffused by the third optical layer 117c to be extracted to the outside of the display apparatus 1000 so that the luminance uniformity of the display apparatus 1000 may be improved.

The third optical layer 117c may be configured by an organic insulating material in which micro particles are dispersed, but the example embodiments of the present disclosure are not limited thereto. For example, the third optical layer 117c may be configured by siloxane in which micro particles, such as titanium dioxide (TiO₂) particles, are dispersed, but the example embodiments of the present disclosure are not limited thereto. For example, the third optical layer 117c may be configured by the same material as the first optical layer 117a, but the example embodiments of the present disclosure are not limited thereto. For example, the third optical layer 117c may be a diffusion layer or an upward diffusion layer, but the example embodiments of the present disclosure are not limited thereto.

According to the present disclosure, light from the plurality of micro LEDs (ED) is scattered by micro particles dispersed in the third optical layer 117c to be emitted to the outside of the display apparatus 1000. The third optical layer 117c uniformly mixes light emitted from the plurality of micro LEDs (ED) to further improve the luminance uniformity of the display apparatus 1000. The light extraction efficiency of the display apparatus 1000 may be improved by light scattered from the plurality of micro particles so that the display apparatus 1000 may be driven at a low power.

In the active area AA, a black matrix BM may be disposed on the second electrode CE2, the first optical layer 117a, the second optical layer 117b, and the third optical layer 117c. For example, the contact hole of the second optical layer 117b may be filled with the black matrix BM. The black matrix BM is configured to cover the active area AA to reduce color mixture and external light reflection of light of the plurality of sub pixels. For example, the black matrix BM is disposed in the contact hole through which the second electrode CE2 and the contact electrode CCE are connected so that light leakage between the plurality of adjacent sub pixels may be suppressed.

For example, the black matrix BM may be configured by an opaque material, but the example embodiments of the present disclosure are not limited thereto. For example, the black matrix BM may be configured by an organic insulating material to which black pigment or black dye is added, but the example embodiments of the present disclosure are not limited thereto.

In the active area AA, a cover layer 118 may be disposed on the black matrix BM. The cover layer 118 may protect configurations below the cover layer 118. For example, the cover layer 118 may be configured by an organic insulating material, but the example embodiments of the present disclosure are not limited thereto. For example, the cover layer 118 may be configured by a photo resist, polyimide (PI), or photo acrylic material, but the example embodiments of the present disclosure are not limited thereto. For example, the cover layer 118 may be an over coating layer or an insulating layer, but the example embodiments of the present disclosure are not limited thereto.

A polarization layer 293 may be disposed on the cover layer 118 by means of the first adhesive layer 291. A cover member 120 may be disposed on the polarization layer 293 by means of the second adhesive layer 295. For example, the first adhesive layer 291 and the second adhesive layer 295 may include an optically clear adhesive (OCA), an optically clear resin (OCR), or a pressure sensitive adhesive (PSA), but the example embodiments of the present disclosure are not limited thereto.

According to the present disclosure, a plurality of pad electrodes PE may be disposed on the third insulating layer 115c in the second non-active area NA2. For example, at least a part of the plurality of pad electrodes PE may be exposed from the passivation layer 116. For example, the plurality of pad electrodes PE may be electrically connected to the 2-4-th connection line 122d through a fourth contact hole CH4, for example, a contact hole of the third insulating layer 115c.

The plurality of pad electrodes PE may be disposed so as to overlap the entire 2-4-th connection line 122d. For example, one ends (for example, first ends) of the plurality of pad electrodes PE may overlap one end (for example, a first end) of the 2-4-th connection line 122d or disposed at the inside more than one end of the 2-4-th connection line 122d. The other end (for example, second ends) of the plurality of pad electrodes PE may be disposed at the outside more than the other end (for example, a second end) of the 2-4-th connection line 122d, but is not limited thereto. Herein, the inside refers to a side more adjacent to the active area AA, and the outside refers to a side more adjacent to an edge of the substrate 110.

For example, the fourth contact hole CH4 which connects the plurality of pad electrodes PE and the 2-4-th connection line 122d may be disposed between the third contact hole CH3 which connects the 2-4-th connection line 122d and the 2-3-th connection line 122c and the second contact hole CH2 which connects the 2-3-th connection line 122c and the 2-2-th connection line 122b. Therefore, at least a part of the plurality of pad electrodes PE may be disposed so as to overlap the 2-3-th connection line 122c. In contrast, the plurality of pad electrodes PE may be disposed so as not to overlap the 2-2-th connection line 122b and the 2-1-th connection line 122a which is disposed inside more than the 2-2-th connection line 122b, but is not limited thereto.

The adhesive layer ACF may be disposed on the plurality of pad electrodes PE. The adhesive layer ACF may be an adhesive layer in which a plurality of conductive balls CB is dispersed in an insulating material, but the example embodiments of the present disclosure are not limited thereto. Therefore, when heat or a pressure is applied to the adhesive layer ACF, the plurality of conductive balls CB is electrically connected in a portion applied with the heat or pressure to have a conductive property. The adhesive layer ACF is disposed between the plurality of pad electrodes PE and the flexible circuit board (or flexible film) FCB, so that the flexible circuit board (or flexible film) FCB may be attached or bonded to the plurality of pad electrodes PE. For example, the adhesive layer ACF may be anisotropic conductive film, but the example embodiments of the present disclosure are not limited thereto.

The flexible circuit board (or flexible film) FCB including a pad PA may be disposed on the adhesive layer ACF. The pad PA of the flexible circuit board (or flexible film) FCB may be electrically connected to the plurality of pad electrodes PE through the adhesive layer ACF. Accordingly, a signal output from the flexible circuit board (or flexible film) FCB and the printed circuit board 160 may be transmitted to the pixel driving circuit PD of the active area AA through the plurality of pad electrodes PE, the 2-4-th connection line 122d, the 2-3-th connection line 122c, the 2-2-th connection line 122b, and the 2-1-th connection line 122a.

As described above, when the flexible circuit board including the pad and the display panel are bonded, an adhesive layer including a plurality of conductive balls may be used. However, the plurality of conductive balls is irregularly dispersed in the adhesive layer so that it is difficult to control an interval between the plurality of conductive balls. Therefore, the plurality of conductive balls clump in a small space formed between the pad of the flexible circuit board and the plurality of pad electrodes of the display panel. Further, even though the plurality of conductive balls is dispersed to be aligned in one line in the adhesive layer, the plurality of conductive balls aligned in one line is concentrated in the small space formed between the plurality of pad electrodes. Therefore, an aligned angular slope is increased by the interference by the plurality of pad electrodes, which results in the clumping of the plurality of conductive balls. As described above, when the plurality of conductive balls clumps between the plurality of pad electrodes, a problem in that the adjacent pad electrodes are electrically shorted occurs. If the adjacent pad electrodes are electrically connected by the short-circuit, as compared with the normal pixel, a luminance is not uniform and an unnecessary signal may be applied to allow a pixel which should not emit light to emit light, which results in poor display quality of the display apparatus. Further, when the plurality of conductive balls clump between the plurality of pad electrodes, the area in which the plurality of conductive balls clump is vulnerable to burnt-out caused by external factors. Therefore, there is a problem in that in the area in which the plurality of conductive balls clump, the burnt-out due to the external factors may be concentrated more than in a normal area in which the conductive balls do not clump.

Specifically, the conductive ball clumping may be more serious when the flatness of the area in which the plurality of pad electrodes is disposed is degraded. For example, when the plurality of connection lines disposed below the plurality of pad electrodes overlaps, a flatness of an upper portion of the plurality of connection lines, that is, an area in which the pad electrode is disposed, may be degraded due to the step between an overlapping area of the connection lines and a non-overlapping area. Accordingly, the angular gradient at which the plurality of conductive balls is aligned may be increased due to the step of the area in which the plurality of pad electrodes is disposed. Therefore, there was a problem in that the clumping of the conductive balls becomes worse.

Therefore, in the display apparatus 1000 according to the example embodiment of the present disclosure, the overlapping area between the second connection lines 122 disposed below the plurality of pad electrodes PE may be minimized or reduced. For example, the 2-1-th connection line 122a, the 2-2-th connection line 122b, the 2-3-th connection line 122c, and the 2-4-th connection line 122d of the second connection line 122 are dispersed from each other to be disposed stepwise. That is, both end portions of the 2-2-th connection line 122b disposed on the 2-1-th connection line 122a are disposed at the outside more than both end portions of the 2-1-th connection line 122a so that a least a part thereof may not overlap the 2-1-th connection line 122a. Both end portions of the 2-3-th connection line 122c disposed on the 2-2-th connection line 122b are disposed at the outside more than both end portions of the 2-2-th connection lines 122b so that at least a part thereof may not overlap the 2-2-th connection line 122b. Further, the 2-3-th connection line 122c may be disposed so as not to overlap the 2-1-th connection line 122a. Likewise, both end portions of the 2-4-th connection line 122d disposed on the 2-3-th connection line 122c are disposed at the outside more than both end portions of the 2-3-th connection line 122c so that a least a part thereof may not overlap the 2-3-th connection line 122c. Further, the 2-4-th connection line 122d may be disposed so as not to overlap the 2-2-th connection line 122b and the 2-1-th connection line 122a. That is, in the display apparatus 1000 according to the example embodiment of the present disclosure, an overlapping area between the second connection lines 122 is minimized or reduced to relieve a step with a surrounding area. Accordingly, the flatness of the upper portion of the second connection line 122, that is, an area in which the plurality of pad electrodes PE is disposed may be ensured. Accordingly, the plurality of conductive balls CB may be uniformly dispersed between the plurality of pad electrodes PE and the pad PA of the flexible circuit board FCB. Therefore, the clumping of the plurality of conductive balls CB may be suppressed. Though four connection lines are illustrated, the number of the connection lines is not limited thereto. For example, when there are no more than two connection lines in an overlapping direction, regardless of the number of the connection lines, flatness of the upper portion of the connection lines may be ensured.

That is, in the display apparatus 1000 according to the example embodiment of the present disclosure, the short-circuit defect caused by the plurality of conductive balls which is simultaneously in contact with the plurality of adjacent pad electrodes PE due to the clumping of the plurality of conductive balls CB to electrically connect the plurality of pad electrodes PE may be minimized or suppressed.

Further, in the display apparatus 1000 according to the example embodiment of the present disclosure, the burnt defect caused when heat or pressure is concentrated on the plurality of conductive balls CB due to the clumping of the plurality of conductive balls CB is minimized or suppressed to improve the lifespan of the display apparatus 1000.

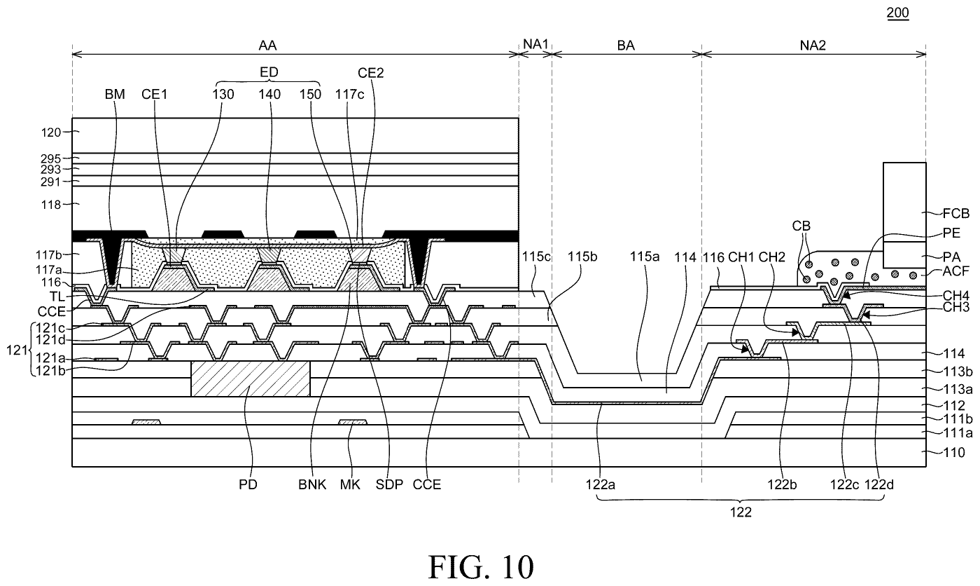

FIG. 10 is a cross-sectional view of a display apparatus according to another example embodiment of the present disclosure. FIG. 10 is a cross-sectional view of the same area as in FIG. 8. The only difference between a display apparatus of FIG. 10 and the display apparatus of FIGS. 1 to 9 is a position of a flexible circuit board FCB and a pad PA of the flexible circuit board FCB of a display panel 200, but the other component is substantially the same, so that a redundant description will be omitted.

As shown in FIG. 10, the flexible circuit board FCB and the pad PA of the flexible circuit board FCB may be disposed so as not to overlap the second connection line 122. For example, the flexible circuit board FCB and the pad PA are disposed at the outside more than the second connection line 122 to overlap only the plurality of pad electrodes PE. That is, the pad PA of the flexible circuit board FCB may overlap only a part of the plurality of pad electrodes PE in which the second connection line 122 is not disposed therebelow. Therefore, a part in which the flexible circuit board FCB is disposed is an area in which a step caused by the overlapping of the second connection line 122 may be less than the other area. That is, the flexible circuit board FCB is disposed in an area which is relatively flat, of the plurality of pad electrodes PE to minimize or suppress clumping of the conductive balls between the pad PA of the flexible circuit board FCB and the plurality of pad electrodes PE due to the improved flatness.

In the display apparatus according to another example embodiment of the present disclosure, the overlapping area between the second connection lines 122 disposed below the plurality of pad electrodes PE may be minimized or reduced. For example, the 2-1-th connection line 122a, the 2-2-th connection line 122b, the 2-3-th connection line 122c, and the 2-4-th connection line 122d of the second connection line 122 are dispersed from each other to be disposed stepwise. That is, both end portions of the 2-2-th connection line 122b disposed on the 2-1-th connection line 122a are disposed at the outside more than both end portions of the 2-1-th connection line 122a so that a least a part thereof may not overlap the 2-1-th connection line 122a. Both end portions of the 2-3-th connection line 122c disposed on the 2-2-th connection line 122b are disposed at the outside more than both end portions of the 2-2-th connection lines 122b so that at least a part thereof may not overlap the 2-2-th connection line 122b. Further, the 2-3-th connection line 122c may be disposed so as not to overlap the 2-1-th connection line 122a. Likewise, both end portions of the 2-4-th connection line 122d disposed on the 2-3-th connection line 122c are disposed at the outside more than both end portions of the 2-3-th connection line 122c so that a least a part thereof may not overlap the 2-3-th connection line 122c. Further, the 2-4-th connection line 122d may be disposed so as not to overlap the 2-2-th connection line 122b and the 2-1-th connection line 122a. That is, in the display apparatus according to another example embodiment of the present disclosure, an overlapping area between the second connection lines 122 is minimized or reduced to relieve a step with a surrounding area. Accordingly, the flatness of the upper portion of the second connection line 122, that is, an area in which the plurality of pad electrodes PE is disposed may be ensured.

Specifically, in the display apparatus according to another example embodiment of the present disclosure, the pad PA of the flexible circuit board FCB may be disposed so as not to overlap the second connection line 122 disposed below the plurality of pad electrodes PE. Therefore, the pad PA of the flexible circuit board FCB may be disposed on a part of the plurality of pad electrodes PE which does not overlap the second connection line 122. That is, the flexible circuit board FCB may be disposed in an area in which a step due to the overlapping of the second connection line 122 is less than the other area in the plurality of pad electrodes PE. Accordingly, in the display apparatus according to another example embodiment of the present disclosure, the flexible circuit board FCB is disposed on a relatively flat area of the area in which the plurality of pad electrodes PE is disposed. Therefore, the plurality of conductive balls CB may be more uniformly dispersed between the plurality of pad electrodes PE and the pad PA of the flexible circuit board FCB. Therefore, the clumping of the plurality of conductive balls CB may be more effectively suppressed.

That is, in the display apparatus according to another example embodiment of the present disclosure, the short-circuit defect caused by the plurality of conductive balls which is simultaneously in contact with the plurality of adjacent pad electrodes PE due to the clumping of the plurality of conductive balls CB to electrically connect the plurality of pad electrodes PE may be minimized or suppressed.

Further, in the display apparatus according to another example embodiment of the present disclosure, the burnt defect caused when heat or pressure is concentrated on the plurality of conductive balls CB due to the clumping of the plurality of conductive balls CB is minimized or suppressed to improve the lifespan of the display apparatus 1000.

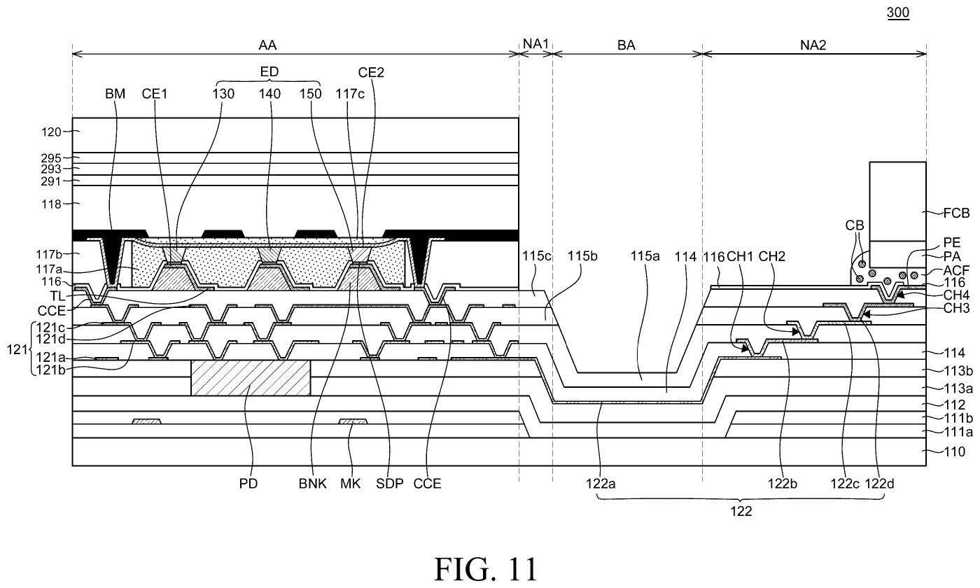

FIG. 11 is a cross-sectional view of a display apparatus according to still another example embodiment of the present disclosure. FIG. 11 is a cross-sectional view of the same area as in FIG. 8. The only difference between a display apparatus of FIG. 11 and the display apparatus of FIGS. 1 to 9 is a placement position of a plurality of pad electrodes PE of a display panel 300, but the other component is substantially the same so that a redundant description will be omitted.

As shown in FIG. 11, a 2-1-th connection line 122a, a 2-2-th connection line 122b, a 2-3-th connection line 122c, a 2-4-th connection line 122d, and a plurality of pad electrodes PE may be dispersed so as to overlap each other in only a minimum area. For example, the 2-1-th connection line 122a, the 2-2-th connection line 122b, the 2-3-th connection line 122c, the 2-4-th connection line 122d, and the plurality of pad electrodes PE may be disposed stepwise. Therefore, the step caused by the difference in thickness of the second connection line 122 between the overlapping areas of the 2-1-th connection line 122a, the 2-2-th connection line 122b, the 2-3-th connection line 122c, and the 2-4-th connection line 122d and a surrounding area may be relieved. Accordingly, the flatness of the upper portion of the second connection line 122 in which the plurality of pad electrodes PE is disposed may be ensured.

For example, the plurality of pad electrodes PE may overlap the 2-4-th connection line 122d in only a partial area and expose a part of the 2-4-th connection line 122d. For example, if it is assumed that between both end portions of the plurality of pad electrodes PE and the 2-4-th connection line 122d, an end portion more adjacent to the active area AA is one end (for example, a first end) and an end portion more adjacent to an edge of the substrate 110 is the other end (for example, a second end), one end (i.e., the first end) of the plurality of pad electrodes PE may be disposed at the outside more than one end (i.e., the first end) of the 2-4-th connection line 122d. Further, the other end (i.e., the second end) of the plurality of pad electrodes PE may be disposed at the outside more than the other end (i.e., the second end) of the 2-4-th connection line 122d. That is, both end portions of the plurality of pad electrodes PE are respectively disposed at the outside more than both end portions of the 2-4-th connection line 122d so as not to at least partially overlap the 2-4-th connection line 122d, but is not limited thereto.

In the meantime, the plurality of pad electrodes PE may be disposed so as not to overlap the 2-3-th connection line 122c. For example, the plurality of pad electrodes PE may be disposed at the outside of the 2-3-th connection line 122c. That is, one end (i.e., the first end) of the plurality of pad electrodes PE may be disposed at the outside more than the other end (i.e., the second end) of the 2-3-th connection line 122c.

Therefore, a fourth contact hole CH4 which connects the plurality of pad electrodes PE and the 2-4-th connection line 122d also may not overlap the 2-3-th connection line 122c. Accordingly, the fourth contact hole CH4 may be disposed at the outside more than the third contact hole CH3 which connects the 2-3-th connection line 122c and the 2-2-th connection line 122b, but is not limited thereto.

In the meantime, the other end (i.e., the second end) of the 2-3-th connection line 122c is disposed at the outside more than the other end (i.e., the second end) of the 2-2-th connection line 122b and one end (i.e., the first end) of the plurality of pad electrodes PE is disposed at the outside more than the other end (i.e., the second end) of the 2-3-th connection line 122c. Therefore, the plurality of pad electrodes PE may not overlap the 2-2-th connection line 122b. Therefore, a fourth contact hole CH4 which connects the plurality of pad electrodes PE and the 2-4-th connection line 122d may also not overlap the 2-2-th connection line 122b. Further, the plurality of pad electrodes PE does not overlap the 2-2-th connection line 122b so that the plurality of pad electrodes PE may not overlap the second contact hole CH2 which connects the 2-2-th connection line 122b and the 2-3-th connection line 122c, but is not limited thereto.

In the meantime, the other end (i.e., the second end) of the 2-2-th connection line 122b is disposed at the outside more than the other end (i.e., the second end) of the 2-1-th connection line 122a and one end (i.e., the first end) of the plurality of pad electrodes PE is disposed at the outside more than the other end (i.e., the second end) of the 2-2-th connection line 122b. Therefore, the plurality of pad electrodes PE may not overlap the 2-1-th connection line 122a. Therefore, a fourth contact hole CH4 which connects the plurality of pad electrodes PE and the 2-4-th connection line 122d may also not overlap the 2-1-th connection line 122a. Further, the plurality of pad electrodes PE does not overlap the 2-1-th connection line 122a so that the plurality of pad electrodes PE may not overlap the first contact hole CH1 which connects the 2-1-th connection line 122a and the 2-2-th connection line 122b, but is not limited thereto.

In the display apparatus according to still another example embodiment of the present disclosure, the overlapping area between the second connection lines 122 disposed below the plurality of pad electrodes PE may be minimized or reduced. For example, the 2-1-th connection line 122a, the 2-2-th connection line 122b, the 2-3-th connection line 122c, and the 2-4-th connection line 122d of the second connection line 122 are dispersed from each other to be disposed stepwise. That is, both end portions of the 2-2-th connection line 122b disposed on the 2-1-th connection line 122a are disposed at the outside more than both end portions of the 2-1-th connection line 122a so that a least a part thereof may not overlap the 2-1-th connection line 122a. Both end portions of the 2-3-th connection line 122c disposed on the 2-2-th connection line 122b are disposed at the outside more than both end portions of the 2-2-th connection lines 122b so that at least a part thereof may not overlap the 2-2-th connection line 122b. Further, the 2-3-th connection line 122c may be disposed so as not to overlap the 2-1-th connection line 122a. Likewise, both end portions of the 2-4-th connection line 122d disposed on the 2-3-th connection line 122c are disposed at the outside more than both end portions of the 2-3-th connection line 122c so that a least a part thereof may not overlap the 2-3-th connection line 122c. Further, the 2-4-th connection line 122d may be disposed so as not to overlap the 2-2-th connection line 122b and the 2-1-th connection line 122a. That is, in the display apparatus according to still another example embodiment of the present disclosure, an overlapping area between the second connection lines 122 is minimized or reduced to relieve a step with a surrounding area. Accordingly, the flatness of the upper portion of the second connection line 122, that is, an area in which the plurality of pad electrodes PE is disposed may be ensured.

Further, in the display apparatus according to still another example embodiment of the present disclosure, the plurality of pad electrodes PE may be disposed to overlap the second connection lines 122 disposed therebelow only in a minimum area. That is, the plurality of pad electrodes PE may be dispersed to be disposed stepwise so as to overlap the 2-1-th connection line 122a, the 2-2-th connection line 122b, the 2-3-th connection line 122c, and the 2-4-th connection line 122d in only a minimum area. For example, both end portions of the plurality of pad electrodes PE are disposed at the outside more than both end portions of the 2-4-th connection line 122d disposed on the top, among the second connection lines 122 to be disposed so as not to at least partially overlap the 2-4-th connection line 122d. Further, the plurality of pad electrodes PE may be disposed so as not to overlap the 2-3-th connection line 122c and the 2-2-th connection line 122b, and the 2-1-th connection line 122a. That is, in the display apparatus according to still another example embodiment of the present disclosure, not only an overlapping area between the second connection lines 122, but also the overlapping area of the plurality of pad electrodes PE and the second connection line 122 is minimized or reduced. Therefore, the flatness of the area in which the plurality of pad electrodes PE is disposed may be more effectively ensured. Accordingly, the plurality of conductive balls CB may be more uniformly dispersed between the plurality of pad electrodes PE and the pad PA of the flexible circuit board FCB. Therefore, the clumping of the plurality of conductive balls CB may be more effectively suppressed.

Accordingly, in the display apparatus according to still another example embodiment of the present disclosure, the short-circuit defect caused by the plurality of conductive balls which is simultaneously in contact with the plurality of adjacent pad electrodes PE due to the clumping of the plurality of conductive balls CB to electrically connect the plurality of pad electrodes PE may be minimized or suppressed.

Further, in the display apparatus according to still another example embodiment of the present disclosure, the burnt defect caused when heat or pressure is concentrated on the plurality of conductive balls CB due to the clumping of the plurality of conductive balls CB is minimized or suppressed to improve the lifespan of the display apparatus 1000.

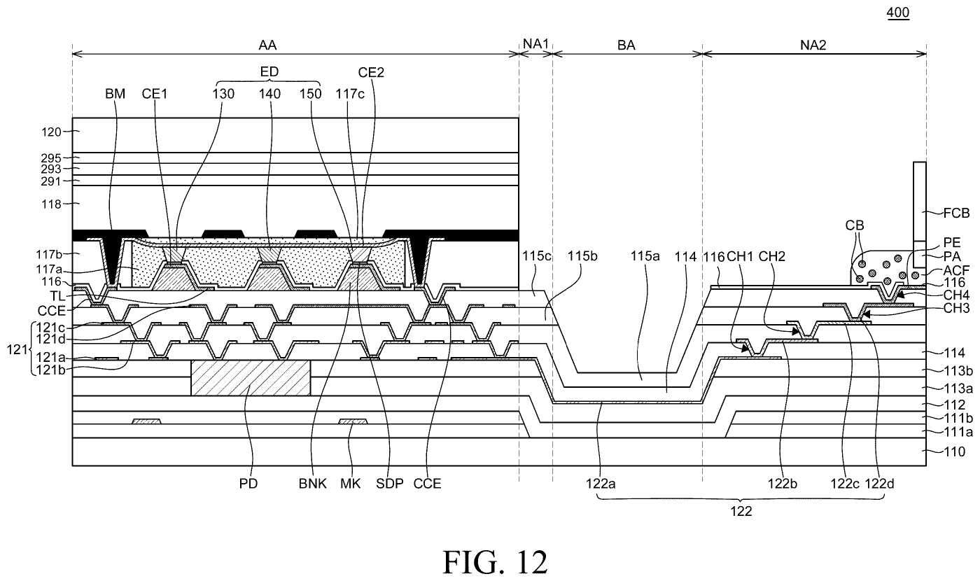

FIG. 12 is a cross-sectional view of a display apparatus according to still another example embodiment of the present disclosure. FIG. 12 is a cross-sectional view of the same area as FIG. 8. The only difference between a display apparatus of FIG. 12 and the display apparatus of FIG. 11 is a position of a flexible circuit board FCB and a pad PA of the flexible circuit board FCB of a display panel 400, but the other component is substantially the same, so that a redundant description will be omitted.

As shown in FIG. 12, the flexible circuit board FCB and the pad PA of the flexible circuit board FCB may be disposed so as not to overlap the second connection line 122. For example, the flexible circuit board FCB and the pad PA are disposed at the outside more than the second connection line 122 to overlap only the plurality of pad electrodes PE. That is, the pad PA of the flexible circuit board FCB may overlap only a part of the plurality of pad electrodes PE in which the second connection line 122 is not disposed therebelow. Therefore, a part in which the flexible circuit board FCB is disposed is an area in which a step caused by the overlapping of the second connection line 122 may be less than the other area. That is, the flexible circuit board FCB is disposed in an area which is relatively flat, of the plurality of pad electrodes PE to minimize or suppress clumping of the conductive balls between the pad PA of the flexible circuit board FCB and the plurality of pad electrodes PE due to the poor flatness.

In the display apparatus according to still another example embodiment of the present disclosure, the overlapping area between the second connection lines 122 disposed below the plurality of pad electrodes PE may be minimized or reduced. For example, the 2-1-th connection line 122a, the 2-2-th connection line 122b, the 2-3-th connection line 122c, and the 2-4-th connection line 122d of the second connection line 122 are dispersed from each other to be disposed stepwise. That is, both end portions of the 2-2-th connection line 122b disposed on the 2-1-th connection line 122a are disposed at the outside more than both end portions of the 2-1-th connection line 122a so that at least a part thereof may not overlap the 2-1-th connection line 122a. Both end portions of the 2-3-th connection line 122c disposed on the 2-2-th connection line 122b are disposed at the outside more than both end portions of the 2-2-th connection lines 122b so that at least a part thereof may not overlap the 2-2-th connection line 122b. Further, the 2-3-th connection line 122c may be disposed so as not to overlap the 2-1-th connection line 122a. Likewise, both end portions of the 2-4-th connection line 122d disposed on the 2-3-th connection line 122c are disposed at the outside more than both end portions of the 2-3-th connection line 122c so that a least a part thereof may not overlap the 2-3-th connection line 122c. Further, the 2-4-th connection line 122d may be disposed so as not to overlap the 2-2-th connection line 122b and the 2-1-th connection line 122a. That is, in the display apparatus according to still another example embodiment of the present disclosure, an overlapping area between the second connection lines 122 is minimized or reduced to relieve a step with a surrounding area. Accordingly, the flatness of the upper portion of the second connection line 122, that is, an area in which the plurality of pad electrodes PE is disposed may be ensured.

Further, in the display apparatus according to still another example embodiment of the present disclosure, the plurality of pad electrodes PE may be disposed to overlap the second connection lines 122 disposed therebelow only in a minimum area. That is, the plurality of pad electrodes PE may be dispersed to be disposed stepwise so as to overlap the 2-1-th connection line 122a, the 2-2-th connection line 122b, the 2-3-th connection line 122c, and the 2-4-th connection line 122d in only a minimum area. For example, both end portions of the plurality of pad electrodes PE are disposed at the outside more than both end portions of the 2-4-th connection line 122d disposed on the top, among the second connection lines 122 to be disposed, so as not to at least partially overlap the 2-4-th connection line 122d. Further, the plurality of pad electrodes PE may be disposed so as not to overlap the 2-3-th connection line 122c and the 2-2-th connection line 122b, and the 2-1-th connection line 122a. That is, in the display apparatus according to still another example embodiment of the present disclosure, not only an overlapping area between the second connection lines 122, but also the overlapping area of the plurality of pad electrodes PE and the second connection line 122 is minimized or reduced. Therefore, the flatness of the area in which the plurality of pad electrodes PE is disposed may be more effectively ensured. Accordingly, the plurality of conductive balls CB may be more uniformly dispersed between the plurality of pad electrodes PE and the flexible circuit board FCB. Therefore, the clumping of the plurality of conductive balls CB may be more effectively suppressed.

Specifically, in the display apparatus according to still another example embodiment of the present disclosure, the pad PA of the flexible circuit board FCB may be disposed so as not to overlap the second connection line 122 disposed below the plurality of pad electrodes PE. Therefore, the pad PA of the flexible circuit board FCB may be disposed on a part of the plurality of pad electrodes PE which does not overlap the second connection line 122. That is, the flexible circuit board FCB may be disposed in an area in which a step due to the overlapping of the second connection line 122 is less than the other area in the plurality of pad electrodes PE. Accordingly, in the display apparatus according to still another example embodiment of the present disclosure, the flexible circuit board FCB is disposed on a relatively flat area of the area in which the plurality of pad electrodes PE is disposed. Therefore, the plurality of conductive balls CB may be more uniformly dispersed between the plurality of pad electrodes PE and the pad PA of the flexible circuit board FCB. Therefore, the clumping of the plurality of conductive balls CB may be more effectively suppressed.

Accordingly, in the display apparatus according to still another example embodiment of the present disclosure, the short-circuit defect caused by the plurality of conductive balls which is simultaneously in contact with the plurality of adjacent pad electrodes PE due to the clumping of the plurality of conductive balls CB to electrically connect the plurality of pad electrodes PE may be minimized or suppressed.

Further, in the display apparatus according to still another example embodiment of the present disclosure, the burnt defect caused when heat or pressure is concentrated on the plurality of conductive balls CB due to the clumping of the plurality of conductive balls CB is minimized or suppressed to improve the lifespan of the display apparatus 1000.

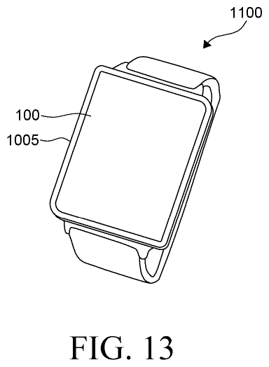

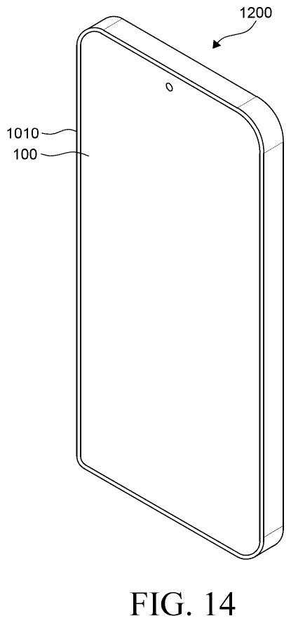

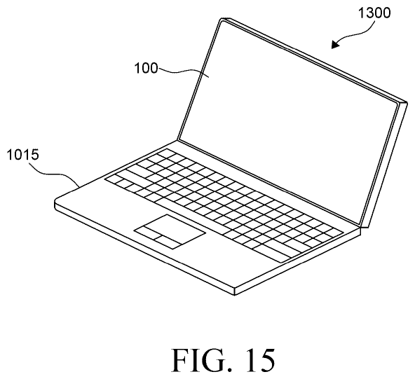

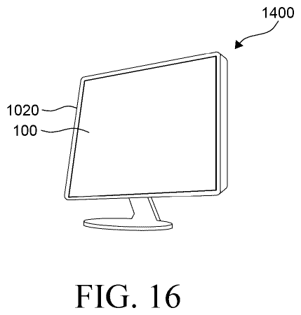

FIGS. 13 to 16 are views illustrating devices to which a display apparatus according to example embodiments of the present disclosure is applied.

As shown in FIGS. 13 to 16, the display apparatus 1000 according to the example embodiments of the present disclosure may be included in various apparatuses or electronic apparatuses. For example, as shown in FIGS. 13 to 16, various electronic apparatuses may include a wearable device 1100, a mobile device 1200, a laptop 1300, and a monitor, or TV 1400, but the example embodiments of the present disclosure are not limited thereto.

Each of the wearable device 1100, the mobile device 1200, the laptop 1300, and the monitor or the TV 1400 may include case parts 1005, 1010, 1015, and 1020, and the display panel 100 (or the display apparatus 1000) according to the example embodiments of the present disclosure described in FIGS. 1 to 12.

For example, the display apparatus according to an example embodiment of the present disclosure may be applied to a mobile device, a video phone, a smart watch, a watch phone, a wearable apparatus, a foldable apparatus, a rollable apparatus, a bendable apparatus, a flexible apparatus, a curved apparatus, a sliding apparatus, a variable apparatus, an electronic notebook, an electronic book, a portable multimedia player (PMP), a personal digital assistant (PDA), an MP3 player, a mobile medical apparatus, a desktop PC, a laptop PC, a netbook computer, a workstation, a navigation system, a vehicle display apparatus, a theater display apparatus, a television, a wallpaper apparatus, a signage apparatus, a game console, a laptop, a monitor, a camera, a camcorder, home appliances, etc.,

The example embodiments of the present disclosure can also be described as follows:

According to an aspect of the present disclosure, there is provided a display apparatus. The display apparatus includes a substrate having an active area, a first non-active area enclosing the active area, a bending area extending from the first non-active area and being bendable, and a second non-active area extending from the bending area, a pixel driving circuit disposed on the substrate in the active area, a protection layer which is disposed so as to enclose the pixel driving circuit, a plurality of banks disposed on the protection layer in the active area, a plurality of micro LEDs which is disposed on the plurality of banks in the active area and is connected to the pixel driving circuit, a plurality of connection lines, at least partially disposed on the protection layer in the second non-active area and a plurality of pad electrodes which is disposed on the plurality of connection lines in the second non-active area. The plurality of connection lines includes a first connection line, a second connection line which is disposed on the first connection line and has one end and the other end respectively disposed at the outside more than one end and the other end of the first connection line, and is connected to the first connection line through a first contact hole, a third connection line which is disposed on the second connection line and has one end disposed at the outside more than the other end of the first connection line, and is connected to the second connection line through a second contact hole and a fourth connection line which is disposed on the third connection line and has one end disposed at the outside more than the other end of the second connection line, and is connected to the third connection line through a third contact hole.

The first contact hole may not overlap the third connection line and the fourth connection line, the second contact hole may not overlap the first connection line and the fourth connection line, and the third contact hole may not overlap the first connection line and the second connection line.

The plurality of pad electrodes may be connected to the fourth connection line through a fourth contact hole, one end of the plurality of pad electrodes may overlap one end of the fourth connection line or may be disposed inside more than one end of the fourth connection line, and the other end of the plurality of pad electrodes may be disposed at the outside more than the other end of the fourth connection line. At least a part of the plurality of pad electrodes may overlap the third connection line. The fourth contact hole may be disposed between the third contact hole and the second contact hole.

The plurality of pad electrodes may be connected to the fourth connection line through a fourth contact hole, and one end and the other end of the plurality of pad electrodes may be respectively disposed at the outside more than one end and the other end of the fourth connection line. The plurality of pad electrodes may be disposed so as not to overlap the first connection line, the second connection line, and the third connection line. The fourth contact hole may be disposed at the outside more than the third contact hole.

The display apparatus may further include a conductive adhesive layer which is disposed on the plurality of pad electrodes and includes a plurality of conductive balls and a flexible circuit board which is disposed on the conductive adhesive layer and is connected to the plurality of pad electrodes through the conductive adhesive layer. The flexible circuit board may be disposed at the outside more than the plurality of connection lines.

The plurality of micro LEDs may include an anode electrode, a first semiconductor layer disposed on the anode electrode, an active layer disposed on the first semiconductor layer, a second semiconductor layer disposed on the active layer and a cathode electrode disposed on the second semiconductor layer.

The display apparatus may further include a first electrode which is disposed below the plurality of micro LEDs to electrically connect the pixel driving circuit and the anode electrodes of the plurality of micro LEDs and a solder pattern which is disposed between the first electrode and the anode electrode. The first electrode and the anode electrode may be electrically connected by eutectic bonding using the solder pattern.

Thicknesses of the plurality of connection lines may be equal to each other in an overlapping area of the first connection line and the second connection line, an overlapping area of the second connection line and the third connection line, and an overlapping area of the third connection line and the fourth connection line.

According to another aspect of the present disclosure, there is provided a display apparatus. The display apparatus includes a substrate having an active area, a first non-active area enclosing the active area, a bending area extending from the first non-active area and being bendable, and a second non-active area which extends from the bending area and has a plurality of pad electrodes and a flexible circuit board connected to the plurality of pad electrodes disposed therein, a pixel driving circuit disposed on the substrate in the active area, a first protection layer and a second protection layer on the first protection layer which are disposed so as to enclose a side surface of the pixel driving circuit, a plurality of micro LEDs which is disposed on the second protection layer in the active area and is connected to the pixel driving circuit and a plurality of connection lines, at least partially disposed between the second protection layer and the plurality of pad electrodes in the second non-active area. The plurality of connection lines includes a first connection line, a second connection line which is disposed so as not to at least partially overlap the first connection line and to be connected to the first connection line, on the first connection line, a third connection line which is disposed so as not to at least partially overlap the second connection line and to be connected to the second connection line, on the second connection line and a fourth connection line which is disposed so as not to at least partially overlap the third connection line and to be connected to the third connection line, on the third connection line.

An end of the second connection line may be disposed at the outside of an end of the first connection line, an end of the third connection line may be disposed at the outside of an end of the second connection line, and an end of the fourth connection line may be disposed at the outside of an end of the third connection line.

The display apparatus may further include a third protection layer disposed on the second protection layer and the pixel driving circuit and a first insulating layer disposed on the third protection layer, a second insulating layer disposed on the first insulating layer, and a third insulating layer disposed on the second insulating layer. The first connection line may be disposed on the second protection layer, the second connection line may be disposed on the third protection layer and may be connected to the first connection line through a contact hole of the third protection layer, the third connection line may be disposed on the first insulating layer and may be connected to the second connection line through a contact hole of the first insulating layer, the fourth connection line may be disposed on the second insulating layer and may be connected to the third connection line through a contact hole of the second insulating layer, a contact hole of the first insulating layer may be disposed at the outside more than an end of the first connection line, and a contact hole of the second insulating layer may be disposed at the outside more than an end of the second connection line.

The plurality of pad electrodes may be disposed on the third insulating layer and may be connected to the fourth connection line through a contact hole of the third insulating layer, and the contact hole of the third insulating layer may be disposed so as to overlap the third connection line, among the plurality of connection lines.

The plurality of pad electrodes may be disposed on the third insulating layer and may be connected to the fourth connection line through a contact hole of the third insulating layer, and the contact hole of the third insulating layer may be disposed at the outside more than an end of the third connection line.

According to another aspect of the present disclosure, there is provided a display apparatus. The display apparatus includes a substrate having an active area and a non-active area; a plurality of micro LEDs disposed in the active area; a plurality of pad electrodes disposed in the non-active area and connected to a flexible circuit board; and a plurality of connection lines each disposed in different layer, at least partially disposed in the non-active area. Some of the plurality of connection lines may overlap with each other, and there may be no more than two connection lines in an overlapping direction.

The plurality of connection lines may include a first connection line and a second connection line which is disposed so as not to at least partially overlap the first connection line and to be connected to the first connection line, on the first connection line.

The plurality of connection lines may further include: a third connection line and a fourth connection line which is disposed so as not to at least partially overlap the third connection line and to be connected to the third connection line, on the third connection line.

The plurality of pad electrodes may be connected to the fourth connection line through a contact hole, and at least a part of the plurality of pad electrodes may overlap the third connection line.

The entire fourth connection line may overlap the plurality of pad electrodes.

The flexible circuit board may be connected to the plurality of pad electrodes through an adhesive layer in which a plurality of conductive balls is dispersed in an insulating material. The plurality of pad electrodes may be disposed so as not to at least partially overlap one of the plurality of connection lines and connected to the one connection line.

The flexible circuit board may be disposed so as not to overlap the one connection line.

Although the example embodiments of the present disclosure have been described in detail with reference to the accompanying drawings, the present disclosure is not limited thereto and may be embodied in many different forms without departing from the technical concept of the present disclosure. Therefore, the example embodiments of the present disclosure are provided for illustrative purposes only and are not intended to limit the technical concept of the present disclosure. The scope of the technical concept of the present disclosure is not limited thereto. Therefore, it should be understood that the above-described example embodiments are illustrative in all aspects and do not limit the present disclosure. All the technical concepts in the equivalent scope of the present disclosure should be construed as falling within the scope of the present disclosure.

What is claimed is:

1. A display apparatus, comprising:
a substrate having an active area, a first non-active area enclosing the active area, a bending area extending from the first non-active area and being bendable, and a second non-active area extending from the bending area;
a pixel driving circuit disposed on the substrate in the active area;
a protection layer which is disposed so as to enclose the pixel driving circuit;
a plurality of banks disposed on the protection layer in the active area;
a plurality of micro LEDs which are disposed on the plurality of banks in the active area and are connected to the pixel driving circuit;
a plurality of connection lines, at least partially disposed on the protection layer in the second non-active area; and
a plurality of pad electrodes which are disposed on the plurality of connection lines in the second non-active area,
wherein the plurality of connection lines include:
a first connection line;
a second connection line which is disposed on the first connection line, has one end and the other end respectively disposed at the outside more than one end and the other end of the first connection line, and is connected to the first connection line through a first contact hole;
a third connection line which is disposed on the second connection line, has one end disposed at the outside more than the other end of the first connection line, and is connected to the second connection line through a second contact hole; and
a fourth connection line which is disposed on the third connection line, has one end disposed at the outside more than the other end of the second connection line, and is connected to the third connection line through a third contact hole.

2. The display apparatus according to claim 1, wherein the first contact hole does not overlap the third connection line and the fourth connection line, the second contact hole does not overlap the first connection line and the fourth connection line, and the third contact hole does not overlap the first connection line and the second connection line.

3. The display apparatus according to claim 1, wherein the plurality of pad electrodes are connected to the fourth connection line through a fourth contact hole, one end of the plurality of pad electrodes overlaps one end of the fourth connection line or is disposed inside more than one end of the fourth connection line, and the other end of the plurality of pad electrodes is disposed at the outside more than the other end of the fourth connection line,
wherein at least a part of the plurality of pad electrodes overlaps the third connection line, and
wherein the fourth contact hole is disposed between the third contact hole and the second contact hole.

4. The display apparatus according to claim 1, wherein the plurality of pad electrodes are connected to the fourth connection line through a fourth contact hole, and one end and the other end of the plurality of pad electrodes are respectively disposed at the outside more than one end and the other end of the fourth connection line,
wherein the plurality of pad electrodes are disposed so as not to overlap the first connection line, the second connection line, and the third connection line, and
wherein the fourth contact hole is disposed at the outside more than the third contact hole.

5. The display apparatus according to claim 1, further comprising:
a conductive adhesive layer which is disposed on the plurality of pad electrodes and includes a plurality of conductive balls; and
a flexible circuit board which is disposed on the conductive adhesive layer and is connected to the plurality of pad electrodes through the conductive adhesive layer,
wherein the flexible circuit board is disposed at the outside more than the plurality of connection lines.

6. The display apparatus according to claim 1, wherein the plurality of micro LEDs include:
an anode electrode;
a first semiconductor layer disposed on the anode electrode;
an active layer disposed on the first semiconductor layer;
a second semiconductor layer disposed on the active layer; and
a cathode electrode disposed on the second semiconductor layer.

7. The display apparatus according to claim 6, further comprising:
a first electrode which is disposed below the plurality of micro LEDs to electrically connect the pixel driving circuit and the anode electrodes of the plurality of micro LEDs; and
a solder pattern which is disposed between the first electrode and the anode electrode,
wherein the first electrode and the anode electrode are electrically connected by eutectic bonding using the solder pattern.

8. The display apparatus according to claim 1, wherein thicknesses of the plurality of connection lines are equal to each other in an overlapping area of the first connection line and the second connection line, an overlapping area of the second connection line and the third connection line, and an overlapping area of the third connection line and the fourth connection line.

9. A display apparatus, comprising:
a substrate having an active area, a first non-active area enclosing the active area, a bending area extending from the first non-active area and being bendable, and a second non-active area which extends from the bending area and has a plurality of pad electrodes and a flexible circuit board connected to the plurality of pad electrodes disposed therein;
a pixel driving circuit disposed on the substrate in the active area;
a first protection layer and a second protection layer on the first protection layer which are disposed so as to enclose a side surface of the pixel driving circuit;
a plurality of micro LEDs which are disposed on the second protection layer in the active area and are connected to the pixel driving circuit; and
a plurality of connection lines, at least partially disposed between the second protection layer and the plurality of pad electrodes in the second non-active area,
wherein the plurality of connection lines includes:
a first connection line;
a second connection line which is disposed so as not to at least partially overlap the first connection line and to be connected to the first connection line, on the first connection line;
a third connection line which is disposed so as not to at least partially overlap the second connection line and to be connected to the second connection line, on the second connection line; and
a fourth connection line which is disposed so as not to at least partially overlap the third connection line and to be connected to the third connection line, on the third connection line.

10. The display apparatus according to claim 9, wherein an end of the second connection line is disposed at the outside of an end of the first connection line, an end of the third connection line is disposed at the outside of an end of the second connection line, and an end of the fourth connection line is disposed at the outside of an end of the third connection line.

11. The display apparatus according to claim 9, further comprising:
a third protection layer disposed on the second protection layer and the pixel driving circuit; and
a first insulating layer disposed on the third protection layer, a second insulating layer disposed on the first insulating layer, and a third insulating layer disposed on the second insulating layer,
wherein the first connection line is disposed on the second protection layer, the second connection line is disposed on the third protection layer and is connected to the first connection line through a contact hole of the third protection layer, the third connection line is disposed on the first insulating layer and is connected to the second connection line through a contact hole of the first insulating layer, the fourth connection line is disposed on the second insulating layer and is connected to the third connection line through a contact hole of the second insulating layer, a contact hole of the first insulating layer is disposed at the outside more than an end of the first connection line, and a contact hole of the second insulating layer is disposed at the outside more than an end of the second connection line.

12. The display apparatus according to claim 11, wherein the plurality of pad electrodes are disposed on the third insulating layer and is connected to the fourth connection line through a contact hole of the third insulating layer, and the contact hole of the third insulating layer is disposed so as to overlap the third connection line, among the plurality of connection lines.

13. The display apparatus according to claim 11, wherein the plurality of pad electrodes are disposed on the third insulating layer and is connected to the fourth connection line through a contact hole of the third insulating layer, and the contact hole of the third insulating layer is disposed at the outside more than an end of the third connection line.

14. A display apparatus, comprising:
a substrate having an active area and a non-active area;
a plurality of micro LEDs disposed in the active area;
a plurality of pad electrodes disposed in the non-active area and connected to a flexible circuit board; and
a plurality of connection lines each disposed in different layer, at least partially disposed in the non-active area,
wherein some of the plurality of connection lines overlap with each other, and
wherein there are no more than two connection lines in an overlapping direction.

15. The display apparatus according to claim 14, wherein the plurality of connection lines include:
a first connection line; and
a second connection line which is disposed so as not to at least partially overlap the first connection line and to be connected to the first connection line, on the first connection line.

16. The display apparatus according to claim 15, wherein the plurality of connection lines further include:
a third connection line; and
a fourth connection line which is disposed so as not to at least partially overlap the third connection line and to be connected to the third connection line, on the third connection line.

17. The display apparatus according to claim 16, wherein the plurality of pad electrodes are connected to the fourth connection line through a contact hole, and
wherein at least a part of the plurality of pad electrodes overlaps the third connection line.

18. The display apparatus according to claim 17, wherein the entire fourth connection line overlaps the plurality of pad electrodes.

19. The display apparatus according to claim 14, wherein the flexible circuit board is connected to the plurality of pad electrodes through an adhesive layer in which a plurality of conductive balls are dispersed in an insulating material, and
wherein the plurality of pad electrodes are disposed so as not to at least partially overlap one connection line among the plurality of connection lines and connected to the one connection line.

20. The display apparatus according to claim 19, wherein the flexible circuit board is disposed so as not to overlap the one connection line.
